(19) United States
(12) Patent Application Publication
(10) Pub. No.: US 2022/0012306 A1
(43) Pub. Date: Jan. 13, 2022

(54) INFORMATION PROCESSING DEVICE, INFORMATION PROCESSING SYSTEM, INFORMATION PROCESSING METHOD, AND STORAGE MEDIUM

(71) Applicants: KABUSHIKI KAISHA TOSHIBA, Tokyo (JP); TOSHIBA DIGITAL SOLUTIONS CORPORATION, Kawasaki-shi Kanagawa (JP)

(72) Inventors: Masaru SUZUKI, Ota Tokyo (JP); Hayato Goto, Kawasaki Kanagawa (JP); Kosuke Tatsumura, Kawasaki Kanagawa (JP)

(73) Assignees: KABUSHIKI KAISHA TOSHIBA, Tokyo (JP); TOSHIBA DIGITAL SOLUTIONS CORPORATION, Kawasaki-shi Kanagawa (JP)

(21) Appl. No.: 17/486,468

(22) Filed: Sep. 27, 2021

Related U.S. Application Data
(63) Continuation of application No. PCT/JP2020/014272, filed on Mar. 27, 2020.

(30) Foreign Application Priority Data
Mar. 28, 2019 (JP) 2019-064276

(51) Int. Cl. G06F 17/16; G06F 7/58; G06F 7/492

(52) U.S. Cl. CPC G06F 17/16; G06F 7/4925; G06F 7/582

(57) ABSTRACT

An information processing device includes a storage unit and a processing circuit. The storage unit is configured to store a first variable and the second variable. The processing circuit is configured to update a first vector having the first variable by weighted addition of the corresponding second variable to the first variable, update a second vector having the second variable by weighting the first variable with a first coefficient that monotonically increases or monotonically decreases depending on the number of updates, adding the weighted first variable to the corresponding second variable, calculating a problem term using a plurality of the first variables, and adding the problem term to the second variable, and repeat updating of the first vector and the second vector, then initialize the second variable of the second vector using a pseudo random number, and then repeat updating of the first vector and the second vector again.

### CROSS REFERENCE TO RELATED APPLICATIONS

This application is continuation application of International Application No. JP2020/014272, filed on Mar. 27, 2020, which claims priority to Japanese Patent Application No. 2019-064276, filed on Mar. 28, 2019, the entire contents of which are incorporated herein by reference.

### FIELD

Embodiments of the present invention relate to an information processing device, an information processing system, an information processing method, and a storage medium.

### BACKGROUND

A combinatorial optimization problem is a problem of selecting a combination most suitable for a purpose from a plurality of combinations. Mathematically, combinatorial optimization problems are attributed to problems for maximizing functions including a plurality of discrete variables, called “objective functions”, or minimizing the functions. Although combinatorial optimization problems are common problems in various fields including finance, logistics, transport, design, manufacture, and life science, it is not always possible to calculate an optimal solution due to so-called “combinatorial explosion” that the number of combinations increases in exponential orders of a problem size. In addition, it is difficult to even obtain an approximate solution close to the optimal solution in many cases.

Development of a technique for calculating a solution for the combinatorial optimization problem within a practical time is required in order to solve problems in each field and promote social innovation and progress in science and technology.

### BRIEF DESCRIPTION OF DRAWINGS

FIG. 1 is a diagram illustrating a configuration example of an information processing system.

FIG. 2 is a block diagram illustrating a configuration example of a management server.

FIG. 3 is a diagram illustrating an example of data stored in a storage unit of the management server.

FIG. 4 is a block diagram illustrating a configuration example of a calculation server.

FIG. 5 is a diagram illustrating an example of data stored in a storage of the calculation server.

FIG. 6 is a flowchart illustrating an example of processing in a case where a solution of a simulated bifurcation algorithm is calculated by time evolution.

FIG. 7 is a flowchart illustrating an example of an algorithm according to a first modified example.

FIG. 8 is a flowchart illustrating an example of an algorithm according to a second modified example.

FIG. 9 is a flowchart illustrating a first example of a process executed in step S114 in FIGS. 7 and 8.

FIG. 10 is a flowchart illustrating a second example of the process executed in step S114 in FIGS. 7 and 8.

FIG. 11 is a table illustrating an example of a coupling coefficient matrix.

FIG. 12 is a table illustrating an example of a local magnetic field vector.

FIG. 13 is a table illustrating an example of a maximum absolute value of a random number.

FIG. 14 is a table illustrating an example of a first vector.

FIG. 15 is a table illustrating an example of a second vector.

FIG. 16 is a table illustrating examples of a solution vector and a Hamiltonian value.

FIG. 17 is a flowchart illustrating an example of an algorithm according to a third modified example.

FIG. 18 is a flowchart illustrating the example of the algorithm according to the third modified example.

FIG. 19 is a flowchart illustrating an example of an algorithm according to a fourth modified example.

FIG. 20 is a table illustrating an example of a coefficient.

FIG. 21 is a flowchart illustrating an example of an algorithm according to a fifth modified example.

FIG. 22 is a flowchart illustrating the example of the algorithm according to the fifth modified example.

FIG. 23 is a graph illustrating an example of a result in a case where calculation is performed according to the algorithm in FIG. 6.

FIG. 24 is a graph illustrating an example of a result in a case where calculation is performed according to the algorithm in FIG. 7.

FIG. 25 is a graph illustrating an example of a result in a case where calculation is performed according to the algorithm in FIGS. 17 and 18.

FIG. 26 is a graph illustrating an example of a result in a case where calculation is performed according to the algorithm in FIGS. 21 and 22.

FIG. 27 is a diagram schematically illustrating an example of a multi-processor configuration.

FIG. 28 is a diagram schematically illustrating an example of a configuration using a GPU.

FIG. 29 is a flowchart illustrating an example of overall processing executed to solve a combinatorial optimization problem.

### DETAILED DESCRIPTION

According to one embodiment, an information processing device is configured to repeatedly update a first vector, which has a first variable as an element, and a second vector, which has a second variable corresponding to the first variable as an element. The information processing device includes a storage unit and a processing circuit. The storage unit is configured to store the first variable and the second variable. The processing circuit is configured to update the first vector by weighted addition of the corresponding second variable to the first variable, update the second vector by weighting the first variable with a first coefficient that monotonically increases or monotonically decreases depending on the number of updates, adding the weighted first variable to the corresponding second variable, calculating a problem term using a plurality of the first variables, and adding the problem term to the second variable, and repeat updating of the first vector and the second vector, then initialize the second variable of the second vector using a pseudo random number, and then repeat updating of the first vector and the second vector again.

Hereinafter, embodiments of the present invention will be described with reference to the drawings. In addition, the same components will be denoted by the same reference signs, and a description thereof will be omitted as appropriate.

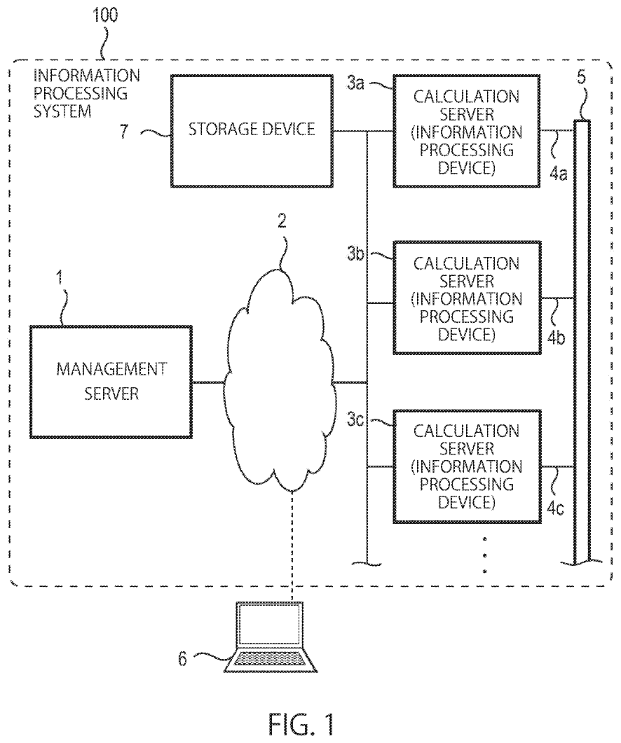

FIG. 1 is a block diagram illustrating a configuration example of an information processing system 100. The information processing system 100 of FIG. 1 includes a management server 1, a network 2, calculation servers (information processing devices) 3a to 3c, cables 4a to 4c, a switch 5, and a storage device 7. In addition, FIG. 1 illustrates a client terminal 6 that can communicate with the information processing system 100. The management server 1, the calculation servers 3a to 3c, the client terminal 6, and the storage device 7 can perform data communication with each other via the network 2. For example, the calculation servers 3a to 3c can store data in the storage device 7 and read data from the storage device 7. The network 2 is, for example, the Internet in which a plurality of computer networks are connected to each other. The network 2 can use a wired or wireless communication medium or a combination thereof. In addition, an example of a communication protocol used in the network 2 is TCP/IP, but a type of communication protocol is not particularly limited.

In addition, the calculation servers 3a to 3c are connected to the switch 5 via the cables 4a to 4c, respectively. The cables 4a to 4c and the switch 5 form interconnection between the calculation servers. The calculation servers 3a to 3c can also perform data communication with each other via the interconnection. The switch 5 is, for example, an Infiniband switch. The cables 4a to 4c are, for example, Infiniband cables. However, a wired LAN switch/cable may be used instead of the Infiniband switch/cable. Communication standards and communication protocols used in the cables 4a to 4c and the switch 5 are not particularly limited. Examples of the client terminal 6 include a notebook PC, a desktop PC, a smartphone, a tablet, and an in-vehicle terminal.

Parallel processing and/or distributed processing can be performed to solve a combinatorial optimization problem. Therefore, the calculation servers 3a to 3c and/or processors of the calculation servers 3a to 3c may share and execute some steps of calculation processes, or may execute similar calculation processes for different variables in parallel. For example, the management server 1 converts a combinatorial optimization problem input by a user into a format that can be processed by each calculation server, and controls the calculation server. Then, the management server 1 acquires calculation results from the respective calculation servers, and converts the aggregated calculation result into a solution of the combinatorial optimization problem. In this manner, the user can obtain the solution to the combinatorial optimization problem. It is assumed that the solution of the combinatorial optimization problem includes an optimal solution and an approximate solution close to the optimal solution.

FIG. 1 illustrates three calculation servers. However, the number of calculation servers included in the information processing system is not limited. In addition, the number of calculation servers used for solving the combinatorial optimization problem is not particularly limited. For example, the information processing system may include one calculation server. In addition, a combinatorial optimization problem may be solved using any one of a plurality of calculation servers included in the information processing system. In addition, the information processing system may include several hundred or more calculation servers. The calculation server may be a server installed in a data center or a desktop PC installed in an office. In addition, the calculation server may be a plurality of types of computers installed at different locations. A type of information processing device used as the calculation server is not particularly limited. For example, the calculation server may be a general-purpose computer, a dedicated electronic circuit, or a combination thereof.

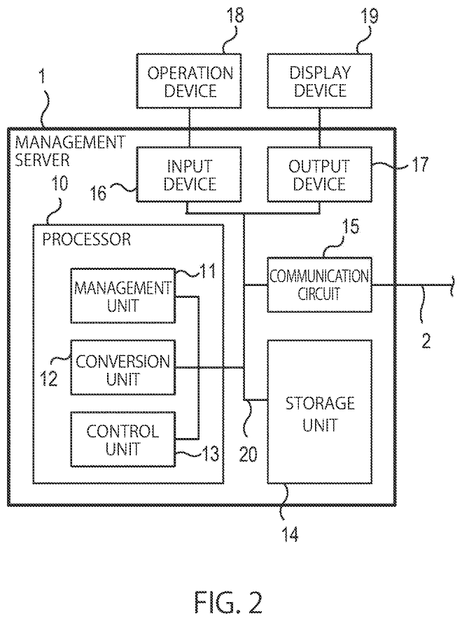

FIG. 2 is a block diagram illustrating a configuration example of the management server 1. The management server 1 of FIG. 2 is, for example, a computer including a central processing unit (CPU) and a memory. The management server 1 includes a processor 10, a storage unit 14, a communication circuit 15, an input circuit 16, and an output circuit 17. It is assumed that the processor 10, the storage unit 14, the communication circuit 15, the input circuit 16, and the output circuit 17 are connected to each other via a bus 20. The processor 10 includes a management unit 11, a conversion unit 12, and a control unit 13 as internal components.

The processor 10 is an electronic circuit that executes an operation and controls the management server 1. The processor 10 is an example of a processing circuit. As the processor 10, for example, a CPU, a microprocessor, an ASIC, an FPGA, a PLD, or a combination thereof can be used. The management unit 11 provides an interface configured to operate the management server 1 via the client terminal 6 of the user. Examples of the interface provided by the management unit 11 include an API, a CLI, and a web page. For example, the user can input information of a combinatorial optimization problem via the management unit 11, and browse and/or download a calculated solution of the combinatorial optimization problem. The conversion unit 12 converts the combinatorial optimization problem into a format that can be processed by each calculation server. The control unit 13 transmits a control command to each calculation server. After the control unit 13 acquires calculation results from the respective calculation servers, the conversion unit 12 aggregates the plurality of calculation results and converts the aggregated result into a solution of the combinatorial optimization problem. In addition, the control unit 13 may designate a processing content to be executed by each calculation server or a processor in each server.

The storage unit 14 stores various types of data including a program of the management server 1, data necessary for execution of the program, and data generated by the program. Here, the program includes both an OS and an application. The storage unit 14 may be a volatile memory, a non-volatile memory, or a combination thereof. Examples of the volatile memory include a DRAM and an SRAM. Examples of the non-volatile memory include a NAND flash memory, a NOR flash memory, a ReRAM, or an MRAM. In addition, a hard disk, an optical disk, a magnetic tape, or an external storage device may be used as the storage unit 14.

The communication circuit 15 transmits and receives data to and from each device connected to the network 2. The communication circuit 15 is, for example, a network interface card (NIC) of a wired LAN. However, the communication circuit 15 may be another type of communication circuit such as a wireless LAN. The input circuit 16 implements data input with respect to the management server 1. It is assumed that the input circuit 16 includes, for example, a USB, PCI-Express, or the like as an external port. In the example of FIG. 2, an operation device 18 is connected to the input circuit 16. The operation device 18 is a device configured to input information to the management server 1. The operation device 18 is, for example, a keyboard, a mouse, a touch panel, a voice recognition device, or the like, but is not limited thereto. The output circuit 17 implements data output from the management server 1. It is assumed that the output circuit 17 includes HDMI, DisplayPort, or the like as an external port. In the example of FIG. 2, the display device 19 is connected to the output circuit 17. Examples of the display device 19 include a liquid crystal display (LCD), an organic electroluminescence (EL) display, and a projector, but are not limited thereto.

An administrator of the management server 1 can perform maintenance of the management server 1 using the operation device 18 and the display device 19. Note that the operation device 18 and the display device 19 may be incorporated in the management server 1. In addition, the operation device 18 and the display device 19 are not necessarily connected to the management server 1. For example, the administrator may perform maintenance of the management server 1 using an information terminal capable of communicating with the network 2.

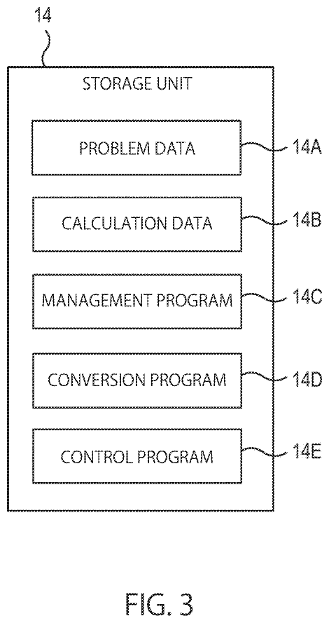

FIG. 3 illustrates an example of data stored in the storage unit 14 of the management server 1. The storage unit 14 of FIG. 3 stores problem data 14A, calculation data 14B, a management program 14C, a conversion program 14D, and a control program 14E. For example, the problem data 14A includes data of a combinatorial optimization problem. For example, the calculation data 14B includes a calculation result collected from each calculation server. For example, the management program 14C is a program that implements the above-described function of the management unit 11. For example, the conversion program 14D is a program that implements the above-described function of the conversion unit 12. For example, the control program 14E is a program that implements the above-described function of the control unit 13.

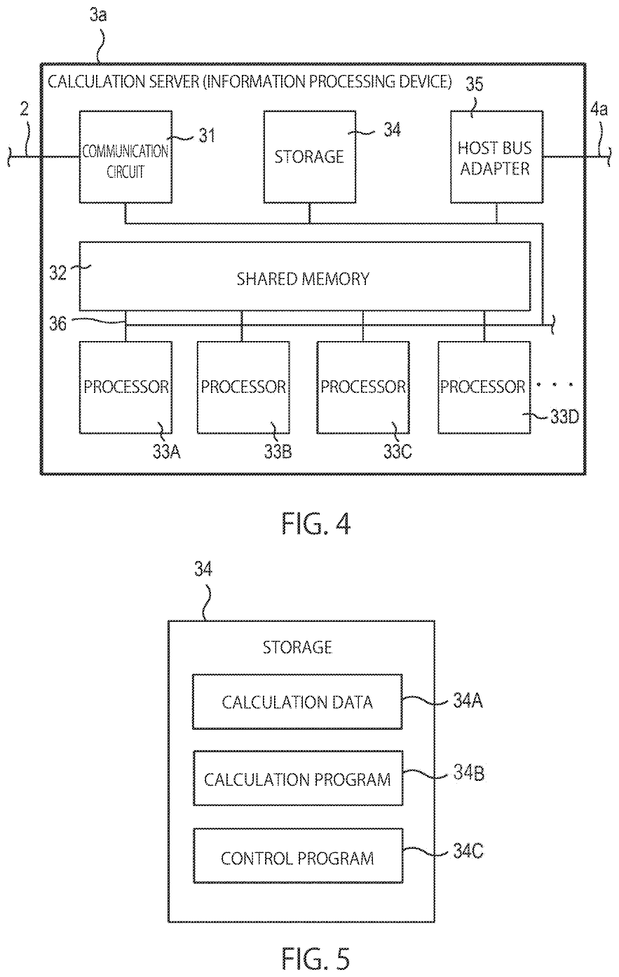

FIG. 4 is a block diagram illustrating a configuration example of the calculation server. The calculation server in FIG. is, for example, an information processing device that calculates a first vector and a second vector alone or in a shared manner with another calculation server.

FIG. 4 illustrates a configuration of the calculation server 3a as an example. The other calculation server may have a configuration similar to that of the calculation server 3a or may have a configuration different from that of the calculation server 3a.

The calculation server 3a includes, for example, a communication circuit 31, a shared memory 32, processors 33A to 33D, a storage 34, and a host bus adapter 35. It is assumed that the communication circuit 31, the shared memory 32, the processors 33A to 33D, the storage 34, and the host bus adapter 35 are connected to each other via a bus 36.

The communication circuit 31 transmits and receives data to and from each device connected to the network 2. The communication circuit 31 is, for example, a network interface card (NIC) of a wired LAN. However, the communication circuit 31 may be another type of communication circuit such as a wireless LAN. The shared memory 32 is a memory accessible from the processors 33A to 33D. Examples of the shared memory 32 include a volatile memory such as a DRAM and an SRAM. However, another type of memory such as a non-volatile memory may be used as the shared memory 32. The shared memory 32 may be configured to store, for example, the first vector and the second vector. The processors 33A to 33D can share data via the shared memory 32. Note that all the memories of the calculation server 3a are not necessarily configured as shared memories. For example, some of the memories of the calculation server 3a may be configured as a local memory that can be accessed only by any processor. Note that the shared memory 32 and the storage 34 to be described later are examples of a storage unit of the information processing device.

The processors 33A to 33D are electronic circuits that execute calculation processes. The processor may be, for example, any of a central processing unit (CPU), a graphics processing unit (GPU), a field-programmable gate array (FPGA), and an application specific integrated circuit (ASIC), or a combination thereof. In addition, the processor may be a CPU core or a CPU thread. When the processor is the CPU, the number of sockets included in the calculation server 3a is not particularly limited. In addition, the processor may be connected to another component of the calculation server 3a via a bus such as PCI express.

In the example of FIG. 4, the calculation server includes four processors. However, the number of processors included in one calculation server may be different from this. For example, the number and/or types of processors implemented on the calculation server may be different. Here, the processor is an example of a processing circuit of the information processing device. The information processing device may include a plurality of processing circuits.

For example, the information processing device is configured to repeatedly update the first vector which has a first variable x, (i=1, 2, . . . , N) as an element and the second vector which has a second variable y, (i=1, 2, . . . , N) corresponding to the first variable as an element. The storage unit of the information processing device may be configured to store the first variable and the second variable.

For example, the processing circuit of the information processing device is configured to update the first vector by weighted addition of the corresponding second variable to the first variable; update the second vector by weighting the first variable with a first coefficient that monotonically increases or monotonically decreases depending on the number of updates, adding the weighted first variable to the corresponding second variable, calculating a problem term using the plurality of first variables, and adding the problem term to the second variable; and repeat updating of the first vector and the second vector, then initialize the second variable of the second vector using a pseudo random number, and then repeat updating of the first vector and the second vector again. The problem term may be calculated based on an Ising model. In addition, the problem term may include a many-body interaction. Details of the first coefficient, the problem term, the Ising model, and the many-body interaction will be described later.

In the information processing device, for example, a processing content (task) can be allocated in units of processors. However, a unit of a calculation resource in which the processing content is allocated is not limited. For example, the processing content may be allocated in units of calculators, or the processing content may be allocated in units of processes operating on a processor or in units of CPU threads.

Hereinafter, components of the calculation server will be described with reference to FIG. 4 again.

The storage 34 stores various data including a program of the calculation server 3 a, data necessary for executing the program, and data generated by the program. Here, the program includes both an OS and an application. The storage 34 may be configured to store, for example, the first vector and the second vector. The storage 34 may be a volatile memory, a non-volatile memory, or a combination thereof. Examples of the volatile memory include a DRAM and an SRAM. Examples of the non-volatile memory include a NAND flash memory, a NOR flash memory, a ReRAM, or an MRAM. In addition, a hard disk, an optical disk, a magnetic tape, or an external storage device may be used as the storage 34.

The host bus adapter 35 implements data communication between the calculation servers. The host bus adapter 35 is connected to the switch 5 via the cable 4a. The host bus adapter 35 is, for example, a host channel adaptor (HCA). The speed of parallel calculation processes can be improved by forming interconnection capable of achieving a high throughput using the host bus adapter 35, the cable 4a, and the switch 5.

FIG. 5 illustrates an example of data stored in the storage of the calculation server. The storage 34 of FIG. 5 stores calculation data 34A, a calculation program 34B, and a control program 34C. The calculation data 34A includes data in the middle of calculation by the calculation server 3a or a calculation result. Note that at least a part of the calculation data 34A may be stored in a different storage hierarchy such as the shared memory 32, a cache of the processor, and a register of the processor. The calculation program 34B is a program that implements a calculation process in each processor and a process of storing data in the shared memory 32 and the storage 34 based on a predetermined algorithm. The control program 34C is a program that controls the calculation server 3a based on a command transmitted from the control unit 13 of the management server 1 and transmits a calculation result of the calculation server 3a to the management server 1.

Next, a technique related to solving a combinatorial optimization problem will be described. An example of the information processing device used to solve the combinatorial optimization problem is an Ising machine. The Ising machine refers to an information processing device that calculates the energy of a ground state of an Ising model. Hitherto, the Ising model has been mainly used as a model of a ferromagnet or a phase transition phenomenon in many cases. In recent years, however, the Ising model has been increasingly used as a model for solving a combinatorial optimization problem. The following Formula (1) represents the energy of the Ising model.

$$[ Formula 1 ]$$

$${E}_{Ising} = {\sum }_{i = 1}^{N} {h}_{i} {s}_{i} + \frac{1}{2} {\sum }_{i = 1}^{N} {\sum }_{j = 1}^{N} {J}_{i , j} {s}_{i} {s}_{j} \qquad ( 1 )$$

Here, sᵢ and sⱼ are spins, and the spins are binary variables each having a value of either +1 or −1. N is the number of spins. Further, hᵢ is a local magnetic field acting on each spin. J is a matrix of coupling coefficients between spins. The matrix J is a real symmetric matrix whose diagonal components are 0. Therefore, Jᵢⱼ indicates an element in row i and column j of the matrix J. Note that the Ising model of Formula (1) is a quadratic expression for the spin, an extended Ising model (Ising model having a many-body interaction) including a third-order or higher-order term of the spin may be used as will be described later.

When the Ising model of Formula (1) is used, energy E_{Ising} can be used as an objective function, and it is possible to calculate a solution that minimizes energy E_{Ising} as much as possible. The solution of the Ising model is expressed in a format of a spin vector (s₁, s₂, . . . , s_{N}). This vector is referred to as a solution vector. In particular, the vector (s₁, s₂, . . . , s_{N}) having the minimum value of the energy E_{Ising} is referred to as an optimal solution. However, the solution of the Ising model to be calculated is not necessarily a strictly optimal solution. Hereinafter, a problem of obtaining an approximate solution (that is, an approximate solution in which a value of the objective function is as close as possible to the optimal value) in which the energy E_{Ising} is minimized as much as possible using the Ising model is referred to as an Ising problem.

Since the spin sᵢ in Formula (1) is a binary variable, conversion with a discrete variable (bit) used in the combinatorial optimization problem can be easily performed using Formula (1+sᵢ)/2. Therefore, it is possible to obtain a solution of the combinatorial optimization problem by converting the combinatorial optimization problem into the Ising problem and causing the Ising machine to perform calculation. A problem of obtaining a solution that minimizes a quadratic objective function having a discrete variable (bit), which takes a value of either 0 or 1, as a variable is referred to as a quadratic unconstrained binary optimization (QUBO) problem. It can be said that the Ising problem represented by Formula (1) is equivalent to the QUBO problem.

For example, a quantum annealer, a coherent Ising machine, a quantum bifurcation machine have been proposed as hardware implementations of the Ising Machine. The quantum annealer implements quantum annealing using a superconducting circuit. The coherent Ising machine uses an oscillation phenomenon of a network formed by an optical parametric oscillator. The quantum bifurcation machine uses a quantum mechanical bifurcation phenomenon in a network of a parametric oscillator with the Kerr effect. These hardware implementations have the possibility of significantly reducing a calculation time, but also have a problem that it is difficult to achieve scale-out and a stable operation.

Therefore, it is also possible to solve the Ising problem using a widely-spread digital computer. As compared with the hardware implementations using the above-described physical phenomenon, the digital computer facilitates the scale-out and the stable operation. An example of an algorithm for solving the Ising problem in the digital computer is simulated annealing (SA). A technique for performing simulated annealing at a higher speed has been developed. However, general simulated annealing is a sequential updating algorithm where each of variables is updated sequentially, and thus, it is difficult to speed up calculation processes by parallelization.

Taking the above-described problem into consideration, a simulated bifurcation algorithm, capable of solving a large-scale combinatorial optimization problem at a high speed by parallel calculation in the digital computer, has been proposed. Hereinafter, a description will be given regarding an information processing device, an information processing system, an information processing method, a storage medium, and a program for solving a combinatorial optimization problem using the simulated bifurcation algorithm.

First, an overview of the simulated bifurcation algorithm will be described.

In the simulated bifurcation algorithm, a simultaneous ordinary differential equation in (2) below is numerically solved for each of two variables xᵢ and yᵢ (i=1, 2, . . . , N), the number of each of the variables being N. Each of the N variables xᵢ corresponds to the spin sᵢ of the Ising model. On the other hand, each of the N variables yᵢ corresponds to the momentum. It is assumed that both the variables xᵢ and yᵢ are continuous variables. Hereinafter, a vector having the variable xᵢ (i=1, 2, . . . , N) as an element is referred to as a first vector, and a vector having the variable yᵢ (i=1, 2, . . . , N) as an element is referred to as a second vector.

$$[ Formula 2 ]$$

$$\frac{{dx}_{i}}{dt} = \frac{\partial H}{\partial {y}_{i}} = {Dy}_{i} \\ \frac{{dy}_{i}}{dt} = - \frac{\partial H}{\partial {x}_{i}} = \{ - D + p ( t ) - {Kx}_{i}^{2} \} {x}_{i} - {ch}_{i} a ( t ) - c {\sum }_{j = 1}^{N} {J}_{ij} {x}_{j} \qquad ( 2 )$$

Here, H is a Hamiltonian of the following Formula (3).

$$[ Formula 3 ]$$

$$H = {\sum }_{i = 1}^{N} [ \frac{D}{2} ( {x}_{i}^{2} + {y}_{i}^{2} ) - \frac{p ( t )}{2} {x}_{i}^{2} + \frac{K}{4} {x}_{i}^{4} + {ch}_{i} {x}_{i} a ( t ) + \frac{c}{2} {\sum }_{j = 1}^{N} {J}_{ij} {x}_{i} {x}_{j} ] \qquad ( 3 )$$

Note that, in (2), a Hamiltonian H′ including a term G (x₁, x₂, . . . , x_{N}) expressed in the following Formula (4) may be used instead of the Hamiltonian H of Formula (3). A function including not only the Hamiltonian H but also the term G (x₁, x₂, . . . , x_{N}) is referred to as an extended Hamiltonian to be distinguished from the original Hamiltonian H.

$$[ Formula 4 ]$$

$${H}^{′} = {\sum }_{i = 1}^{N} [ \frac{D}{2} ( {x}_{i}^{2} + {y}_{i}^{2} ) - \frac{p ( t )}{2} {x}_{i}^{2} + \frac{K}{4} {x}_{i}^{4} + {ch}_{i} {x}_{i} a ( t ) + \frac{c}{2} {\sum }_{j = 1}^{N} {J}_{ij} {x}_{i} {x}_{j} ] + G ( {x}_{1} , {x}_{2} , ⋯ , {x}_{N} ) \qquad ( 4 )$$

Hereinafter, processing will be described by taking a case where the function G (x₁, x₂, . . . , x_{N}) is a correction term as an example. Meanwhile, the function G (x₁, x₂, . . . , x_{N}) may be derived from a constraint condition of a combinatorial optimization problem. However, a method for deriving the function G (x₁, x₂, . . . x_{N}) and a type thereof are not limited. In addition, in Formula (4), the function G (x₁, x₂, . . . , x_{N}) is added to the original Hamiltonian H. However, the function G (x₁, x₂, . . . , x_{N}) may be incorporated into the extended Hamiltonian using a different method.

Referring to the Hamiltonian of Formula (3) and the extended Hamiltonian of Formula (4), each term is either the element xᵢ of the first vector or the element yᵢ of the second vector. As expressed in the following Formula (5), an extended Hamiltonian that can be divided into a term U of the element xᵢ of the first vector and a term V of the element yᵢ of the second vector may be used.

[Formula 5]

H′=U(x₁, . . . , x_{N})+V(y₁, . . . , y_{N}) (5)

In calculation of time evolution of the simulated bifurcation algorithm, values of the variables xᵢ and yᵢ (i=1, 2, . . . , N) are repeatedly updated. Then, the spin sᵢ (i=1, 2, . . . , N) of the Ising model can be obtained by converting the variable xᵢ when a predetermined condition is satisfied. Hereinafter, processing will be described assuming a case where the time evolution is calculated. However, the simulated bifurcation algorithm may be calculated using a scheme other than the time evolution.

In (2) and (3), a coefficient D corresponds to detuning. A coefficient p(t) corresponds to the above-described first coefficient and is also referred to as a pumping amplitude. In the calculation of the time evolution, a value of the coefficient p(t) can be monotonically increased depending on the number of updates. An initial value of the coefficient p(t) may be set to 0.

Note that a case where the first coefficient p(t) is a positive value and a value of the first coefficient p(t) increases depending on the number of updates will be described as an example hereinafter. However, the sign of the algorithm to be presented below may be inverted, and the first coefficient p(t) as a negative value may be used. In this case, the value of the first coefficient p(t) monotonically decreases depending on the number of updates. In either case, however, the absolute value of the first coefficient p(t) monotonically increases depending on the number of updates.

A coefficient K corresponds to a positive Kerr coefficient. As a coefficient c, a constant coefficient can be used. For example, a value of the coefficient c may be determined before execution of calculation according to the simulated bifurcation algorithm. For example, the coefficient c can be set to a value close to an inverse number of the maximum eigenvalue of the J⁽²⁾ matrix. For example, a value of c=0.5 D√(N/2n) can be used. Here, n is the number of edges of a graph related to the combinatorial optimization problem. In addition, a(t) is a coefficient that increases with p(t) at the time of calculating the time evolution. For example, √(p(t)/K) can be used as a(t). Note that the vector hᵢ of the local magnetic field in (3) and (4) can be omitted.

For example, when the value of the coefficient p(t) exceeds a predetermined value, a solution vector having the spin sᵢ as an element can be obtained by converting a variable xᵢ, which is a positive value, into +1 and a variable xᵢ, which is a negative value, into −1 in the first vector. This solution vector corresponds to the solution of the Ising problem. Note that it may be determined whether to obtain a solution vector by executing the above-described conversion based on the number of updates of the first vector and the second vector.

In the case of performing the calculation of the simulated bifurcation algorithm, the solution can be performed by converting the above-described (2) into a discrete recurrence formula using the Symplectic Euler method. The following (6) represents an example of the simulated bifurcation algorithm after being converted into the recurrence formula.

$$[ Formula 6 ]$$

$${x}_{i} ( t + Δ t ) = {x}_{i} ( t ) + {Dy}_{i} ( t ) Δ t \\ {y}_{i} ( t + Δ t ) = {y}_{i} ( t ) + [ \{ - D + p ( t + Δ t ) - {Kx}_{i}^{2} ( t + Δ t ) \} {x}_{i} ( t + Δ t ) ] Δ t - {ch}_{i} a ( t + Δ t ) Δ t - c Δ t {\sum }_{j = 1}^{N} {J}_{i . j} {x}_{j} ( t + Δ t ) \qquad ( 6 )$$

Here, t is time, and Δt is a time step (time increment). Note that the time t and the time step Δt are used to indicate the correspondence relationship with the differential equation in (6). However, the time t and the time step Δt are not necessarily included as explicit parameters when actually implementing the algorithm in software or hardware. For example, if the time step Δt is 1, the time step Δt can be removed from the algorithm at the time of implementation. In a case where the time t is not included as the explicit parameter when the algorithm is implemented, xᵢ(t+Δt) may be interpreted as an updated value of xᵢ(t) in (6). That is, “t” in the above-described (6) indicates a value of the variable before update, and “t+Δt” indicates a value of the variable after update.

In (6), the term described in the third line is derived from the Ising energy. Since a format of this term is determined depending on a problem to be solved, the term is referred to as a problem term.

In the case of calculating the time evolution of the simulated bifurcation algorithm, the value of the spin sᵢ can be obtained based on the sign of the variable xᵢ after increasing the value of p(t) from the initial value (for example, 0) to a predetermined value. For example, if a signum function of sgn(xᵢ)=+1 when xᵢ>0 and sgn(xᵢ)=−1 when xᵢ<0 is used, the value of the spin sᵢ can be obtained by converting the variable xᵢ with the signum function when the value of p(t) increases to the predetermined value. As the signum function, for example, it is possible to use a function that enables sgn(xᵢ)=xᵢ/|xᵢ| when xᵢ≠0 and sgn(xᵢ)=+1 or −1 when xᵢ=0. A timing of obtaining the solution (for example, the spin s, of the Ising model) of the combinatorial optimization problem is not particularly limited. For example, the solution (solution vector) of the combinatorial optimization problem may be obtained when the number of updates of the first vector and the second vector, the value of the first coefficient p, or the value of the objective function becomes larger than a threshold.

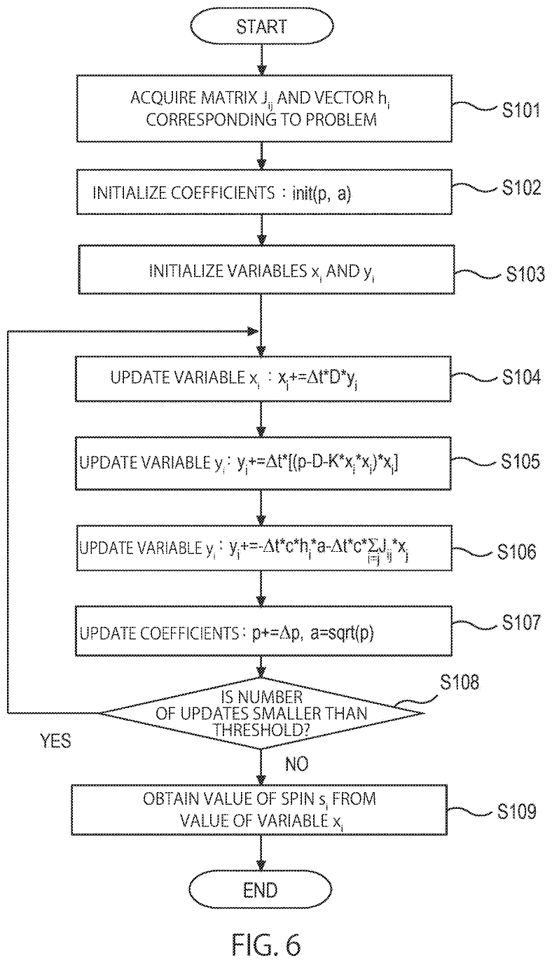

The flowchart of FIG. 6 illustrates an example of processing in the case where the solution of the simulated bifurcation algorithm is calculated by the time evolution. Hereinafter, the processing will be described with reference to FIG. 6.

First, the calculation server acquires the matrix and the vector hᵢ corresponding to a problem from the management server 1 (step S101). Then, the calculation server initializes the coefficients p(t) and a(t) (step S102). For example, values of the coefficients p and a can be set to 0 in step S102, but the initial values of the coefficients p and a are not limited. Next, the calculation server initializes the first variable xᵢ and the second variable yᵢ (step S103). Here, the first variable xᵢ is an element of the first vector. In addition, the second variable yᵢ is an element of the second vector. In step S103, the calculation server may initialize xᵢ and yᵢ to 0, for example. However, a method for initializing xᵢ and yᵢ is not limited. The variables may be initialized at a timing different from the above timing as will be described later. In addition, at least one of the variables may be initialized a plurality of times.

Next, the calculation server updates the element xᵢ of the corresponding first vector based on the element yᵢ of the second vector (step S104). For example, the calculation server updates the first vector by performing weighted addition of the element yᵢ of the corresponding second vector to the element xᵢ of the first vector in step S104. For example, Δt×D×yᵢ can be added to the variable xᵢ in step S104. Then, the calculation server updates the element yᵢ of the second vector (steps S105 and S106). For example, Δt×[(p−D−K×xᵢ×xᵢ)×xᵢ] can be added to the variable yᵢ in step S105. In step S106, −Δt×c×hᵢ×a−Δt×c×ΣJᵢⱼ×xⱼ can be further added to the variable yᵢ.

Next, the calculation server updates the values of the coefficients p and a (step S107). For example, a constant value (Δp) may be added to the coefficient p, and the coefficient a may be set to a positive square root of the updated coefficient p. However, this is merely an example of a method for updating the values of the coefficients p and a as will be described later. Then, the calculation server determines whether the number of updates of the first vector and the second vector is smaller than the threshold (step S108). When the number of updates is smaller than the threshold (YES in step S108), the calculation server executes the processes of steps S104 to S107 again. When the number of updates is equal to or larger than the threshold (NO in step S108), the spin sᵢ, which is the element of the solution vector, is obtained based on the element xᵢ of the first vector (step S109). In step S109, the solution vector can be obtained, for example, in the first vector by converting the variable xᵢ which is the positive value into +1 and the variable xᵢ which is the negative value into −1.

Note that when the number of updates is smaller than the threshold in the determination in step S108 (YES in step S108), a value of the Hamiltonian may be calculated based on the first vector, and the first vector and the value of the Hamiltonian may be stored. As a result, a user can select an approximate solution closest to the optimal solution from the plurality of first vectors.

Note that at least one of the processes illustrated in the flowchart of FIG. 6 may be executed in parallel. For example, the processes of steps S104 to S106 may be executed in parallel such that at least some of the N elements included in each of the first vector and the second vector are updated in parallel. For example, the processes may be performed in parallel using a plurality of calculation servers. The processes may be performed in parallel by a plurality of processors. However, an implementation for realizing parallelization of the processes and a mode of the parallelization of the processes are not limited.

The execution order of processes of updating the variables xᵢ and yᵢ illustrated in steps S105 to S106 described above is merely an example. Therefore, the processes of updating the variables xᵢ and yᵢ may be executed in a different order. For example, the order in which the process of updating the variable xᵢ and the process of updating the variable yᵢ are executed may be interchanged. In addition, the order of sub-processing included in the process of updating each variable is not limited. For example, the execution order of the addition process for the variable yᵢ may be different from the example of FIG. 6. The execution order and timing of processing as a precondition for executing the process of updating each variable are also not particularly limited. For example, the calculation process of the problem term may be executed in parallel with other processes including the process of updating the variable xᵢ. The same applies to the processing in each flowchart to be described hereinafter, in that the execution order and timings of the processes of updating the variables xᵢ and yᵢ, the sub-processing included in the process of updating each variable, and the calculation process of the problem term are not limited.

### [Variation of Variable Initialization Process]

The first vector obtained by the calculation process of the optimization problem does not necessarily correspond to an optimal solution or an approximate solution (referred to as a practical solution) close thereto. For example, the first vector obtained after execution of the processing of the flowchart of FIG. 6 is likely to be a local solution different from the practical solution. In addition, depending on a shape of a potential formed by the extended Hamiltonian, the first vector is likely to stick to the vicinity of the local solution from the middle of the calculation process (for example, any iteration in the loop processing of FIG. 6). In addition, it is desirable to use an algorithm capable of searching a wide range of a solution space in order to obtain the practical solution within a limited calculation time.

In the flowchart of FIG. 6, the process of initializing the first variable xᵢ and the second variable yᵢ is executed before the start of the loop processing related to the update of the first variable xᵢ and the second variable yᵢ. However, the number of times and the timing at which the first variable xᵢ and the second variable yᵢ are initialized are not limited. For example, when the simulated bifurcation algorithm is interpreted as a physical model that calculates motion states of N particles, the first variable xᵢ corresponds to a position of each particle, and the second variable yᵢ corresponds to a momentum of each particle. Therefore, the process of initializing the second variable yᵢ corresponds to a process of changing the motion state of the corresponding particle if the physical model is taken as an example. For example, the frequency of changing the motion state of the corresponding particle can be increased if the number of times of executing the process of initializing the second variable yᵢ is increased. In addition, the motion state of the corresponding particle can be randomly changed if the second variable yᵢ is initialized using a pseudo random number. In each iteration, the first variable xᵢ is updated based on a value of the second variable yᵢ, and thus, the behavior of the first variable xᵢ during the calculation process also changes if the number of times of executing the initialization of the second variable yᵢ is increased. As a result, it is possible to prevent the first vector from sticking to the vicinity of the local solution in the middle of the calculation process and to search a wider region of the solution space. Since a plurality of local solutions can be searched, it is possible to increase a probability that an optimal solution or an approximate solution close to the optimal solution can be obtained by calculation process.

Note that types of random numbers to be used are not limited in a case where the process of initializing the first variable xᵢ and the second variable yᵢ is performed using the pseudo random number. For example, the variables may be initialized using uniform random numbers, or the variables may be initialized using normal random numbers.

That is, the pseudo random number generated by the processing circuit of the information processing device may be the normal random number. In addition, the pseudo random number generated by the processing circuit of the information processing device may be the uniform random number.

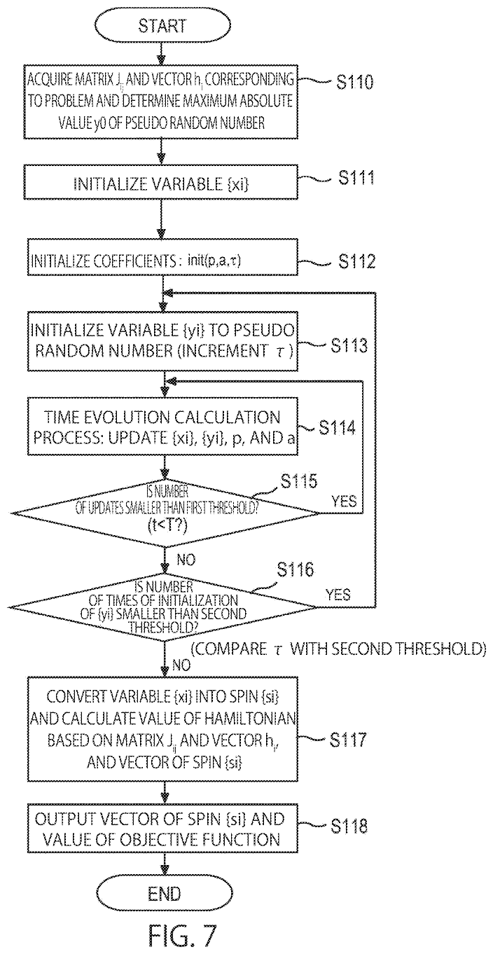

The flowchart of FIG. 7 illustrates an example of an algorithm according to a first modified example. Hereinafter, processing will be described with reference to FIG. 7. Here, the first variable xᵢ is an element of the first vector, and the second variable yᵢ is an element of the second vector.

First, the calculation server acquires the matrix Jᵢⱼ and the vector hᵢ corresponding to a problem from the management server 1, and determines a maximum absolute value y0 of the pseudo random number (step S110). For example, when y0=0.1 is set, a pseudo random number of (−0.1, +0.1) is generated. However, the set value of y0 may be different from this. For example, the set value of y0 can be increased when it is desired to increase the change amount of the first variable xᵢ after the initialization of the second variable yᵢ. In addition, the set value of y0 can be decreased when it is desired to suppress the change amount of the first variable xᵢ after the initialization of the second variable yᵢ. Note that a seed s0 of the pseudo random number may be determined at the timing of step S110. The seed s0 of the pseudo random number may be an automatically determined value or a value designated by the user.

Next, the calculation server initializes the first variable xᵢ (step S111). For example, x, may be initialized to a pseudo random number. In addition, xi may be initialized to 0, and a method for initializing xᵢ is not limited. Then, the calculation server initializes coefficients p(t), a(t), and τ (step S112). In addition, the variable t may be initialized in step S112. For example, the values of p, a, τ, and t can be set to 0 in step S112, but the initial values of p, a, τ, and t are not limited.

Next, the calculation server initializes the second variable yᵢ using a pseudo random number (step S113). Note that the calculation server may increment the counter variable τ in step S113 in order to perform a determination process in step S116 to be described later. As a result, the number of times of initialization of the second variable yᵢ can be counted. In addition, the counter variable t may be initialized in step S113 in a case where the counter variable t is used in determination in step S115 to be described later. For example, the value of t can be set to 0.

Then, the calculation server executes a time evolution calculation process, and updates the first variable xᵢ, the second variable yᵢ, the coefficient p, and the coefficient a (step S114). For example, the calculation server can execute the processes corresponding to steps S 104 to S 107 in FIG. 6 in step S114.

When the variable t is used, for example, At may be added to t.

Next, the calculation server determines whether the number of updates of the first vector and the second vector is smaller than a first threshold (step S115). When the number of updates is smaller than the first threshold (YES in step S115), the calculation server executes the process in step S114 again. When the number of updates is equal to or larger than the first threshold (NO in step S115), the calculation server determines whether the number of times of initialization of the second variable yᵢ is smaller than a second threshold (step S116). In this case, the value of the counter variable τ can be compared with the second threshold in step S116.

When the number of times of initialization of the second variable yᵢ is smaller than the second threshold (YES in step S116), the calculation server executes the processes of step S113 and the subsequent steps again. That is, the calculation server initializes the second variable yᵢ using the pseudo random number (step S113), and then executes the time evolution calculation process (step S114). When the number of times of initialization of the second variable yᵢ is equal to or larger than the second threshold (NO in step S116), the calculation server converts the first variable xᵢ into spin sᵢ, and calculates a value of the Hamiltonian based on the matrix Jᵢⱼ, the vector hᵢ, and the spin sᵢ (step S117). For example, a value of an energy function can be calculated based on (1) in step S117.

Note that the calculation server may store the first vector in a storage area after executing each iteration in the loop processing (for example, the timing of step S115 or step S116). Similarly, the calculation server may store the second vector in a storage area after executing each iteration in the loop processing (for example, the timing of step S115 or step S116). In this case, the calculation server can calculate a value of the extended Hamiltonian using a plurality of combinations of the first vector and the corresponding second vector in step S117. As a result, the calculation server can select the first vector closest to the optimal solution based on the value of the extended Hamiltonian. Then, the calculation server may convert the selected first vector into a vector (solution vector) of the spin sᵢ.

Then, the calculation server outputs the vector of the spin sᵢ and the value of the objective function (step S118). For example, the calculation server may display the vector of the spin sᵢ and the value of the Hamiltonian on a screen of the client terminal 6. In addition, the calculation server may store the vector of the spin sᵢ and the value of the Hamiltonian in an external storage device or a storage of a cloud.

Steps S117 and S118 may be executed by an information processing device other than the calculation server. For example, the management server 1 may execute the processes of step S117 and step S118. In addition, contents of the processes executed at the timings of step S117 and step S118 may be different from those in FIG. 7. For example, a value of the Hamiltonian of (3) or (4) may be calculated, instead of calculating the value of the energy function of (1). Then, the first vector closest to the optimal solution may be selected based on the value of the Hamiltonian. In a case where parameters of the Hamiltonian do not include the spin sᵢ, a process of converting the first vector into the solution vector may be skipped.

When the value of the objective function or the extended Hamiltonian, the closeness of the first vector to the optimal solution can be evaluated. For example, in a case where the definitions of (1), (3), and (4) are used, the first vector is closer to the optimal solution as the value of the Hamiltonian is smaller. Therefore, a process of calculating the value of the objective function or the extended Hamiltonian can be referred to as a solution evaluation process. Although the solution evaluation process is executed in step S117 in the flowchart of FIG. 7, the solution evaluation process may be executed at a timing different from this. For example, the solution evaluation process may be executed after execution of each iteration in the loop processing (for example, the timing of step S115 or step S116). Note that not only the first vector but also the value of the corresponding objective function or extended Hamiltonian may be stored in a storage area in the solution evaluation process.

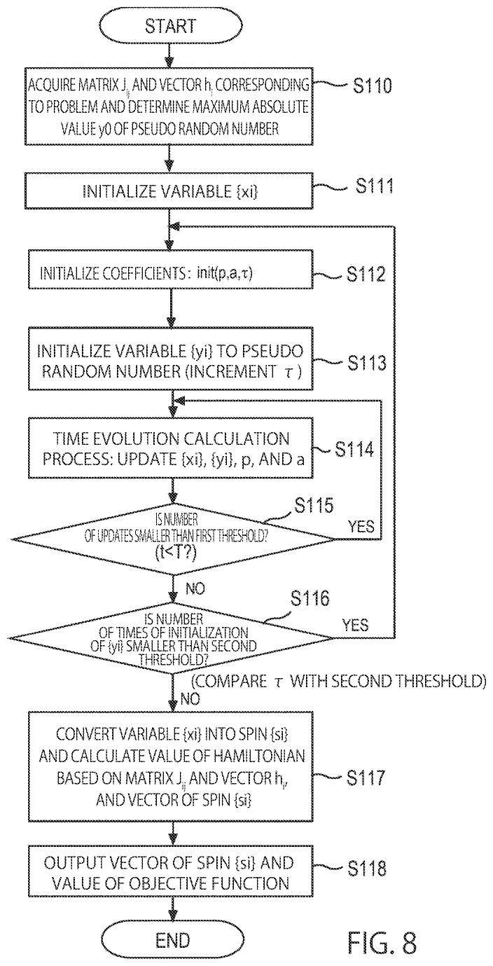

The flowchart of FIG. 8 illustrates an example of an algorithm according to a second modified example. The flowchart of FIG. 8 is different from the flowchart of FIG. 7 in terms of processes executed when the determination in step S116 is positive (the number of times of initialization of the second variable yᵢ is smaller than the second threshold). In the flowchart of FIG. 8, when the number of times of initialization of the second variable yᵢ is smaller than the second threshold (YES in step S116), not only the process of initializing the second variable yi (step S113) but also the process of initializing the coefficients p(t) and a(t) (step S112) is executed. Except for this difference, the processing executed in the flowchart of FIG. 8 is similar to that in the flowchart of FIG. 7.

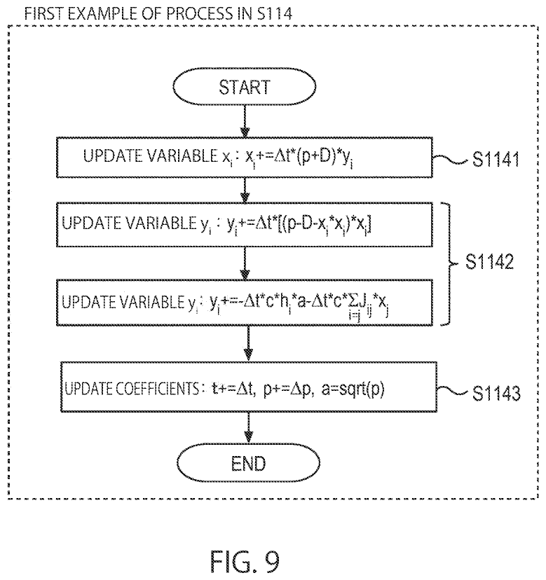

The flowchart of FIG. 9 illustrates a first example of the process executed in step S114 of FIGS. 7 and 8. In the flowchart of FIG. 9, processing corresponding to the time evolution is executed in the order of a process of updating the first variable xᵢ (step S1141), a process of updating the second variable yᵢ (step S1142), and a processing of updating t, p, and a (step S1143).

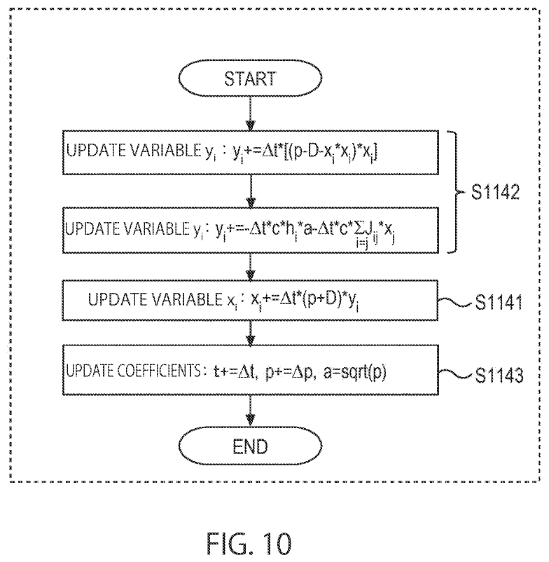

On the other hand, the flowchart of FIG. 10 illustrates a second example of the process executed in step S114 of FIGS. 7 and 8. In the flowchart of FIG. 10, processing corresponding to the time evolution is executed in the order of the process of updating the second variable yᵢ (step S1142), the process of updating the first variable xᵢ (step S1141), and the process of updating t, p, and a (step S1143). In this manner, the first variable xᵢ may be updated first, or the second variable yᵢ may be updated first in step S114. The execution order of the processes of updating the respective variables and sub-processes in the processes of updating the respective variables is not limited.

The time evolution calculation process illustrated in FIG. 9 and FIG. 10 is merely an example. Therefore, the time evolution calculation process may be different from the processes illustrated in FIGS. 9 and 10.

Next, an example of data used in processing executed in the information processing device or the information processing system will be described.

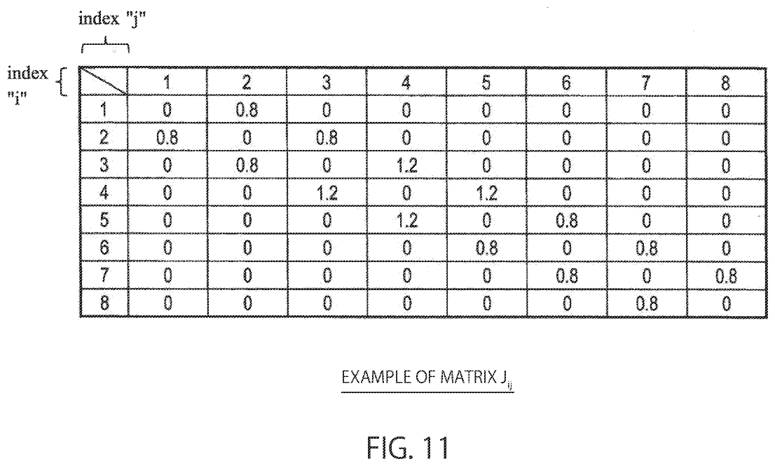

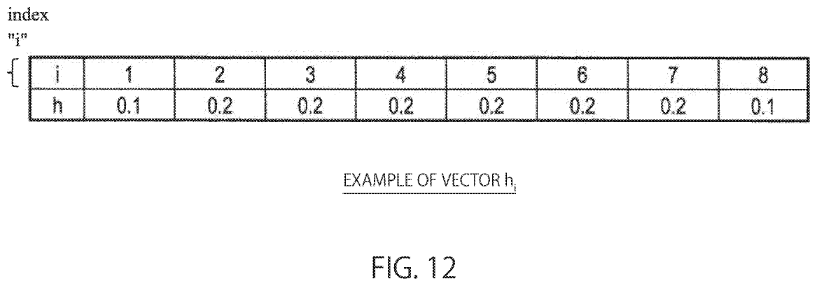

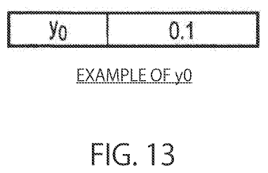

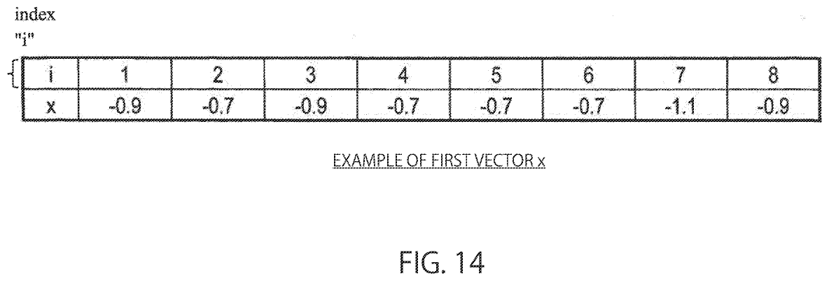

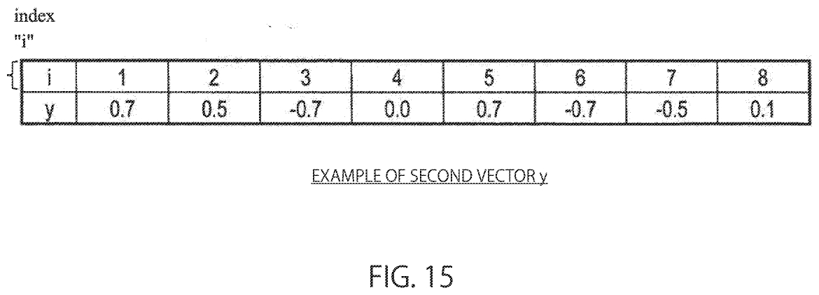

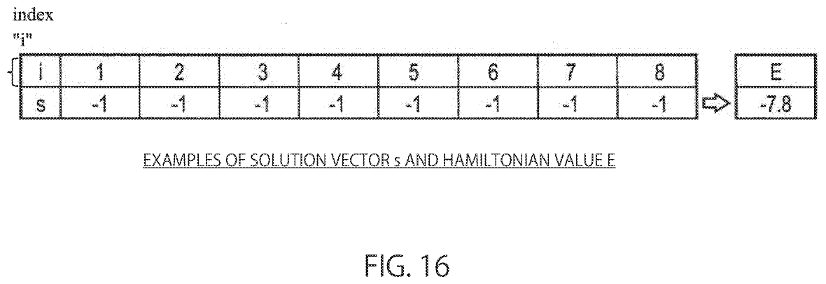

A table in FIG. 11 illustrates an example of the matrix in (1) to (4) and (6). A table of FIG. 12 illustrates an example of the vector hᵢ in (1) to (4) and (6). FIG. 13 illustrates an example of the maximum absolute value y0 of the random number. FIG. 14 illustrates an example of the first vector obtained when y0 in FIG. 13 is used. On the other hand, FIG. 15 illustrates an example of the second vector obtained when y0 in FIG. 13 is used. FIG. 16 illustrates examples of the solution vector and the Hamiltonian value obtained in step S117 in FIG. 7 or 8.

As the algorithm illustrated in FIGS. 7 to 10 described above is executed, it is possible to search the wider range of the solution space regardless of the number of local solutions. Therefore, the practical solution can be obtained within the limited calculation time. In addition, it is possible to solve the combinatorial optimization problem having a larger scale within a shorter time.

[Case where Hamiltonian is Calculated Plurality of Times and Comparison is Performed]

The flowcharts in FIGS. 7 to 10 are merely examples of processing that can be executed by the information processing device and the information processing system. Therefore, the information processing device and the information processing system may obtain the solution of the combinatorial optimization problem by processing different from this. Hereinafter, an example of processing in a case where the Hamiltonian is calculated a plurality of times and comparison is performed will be described.

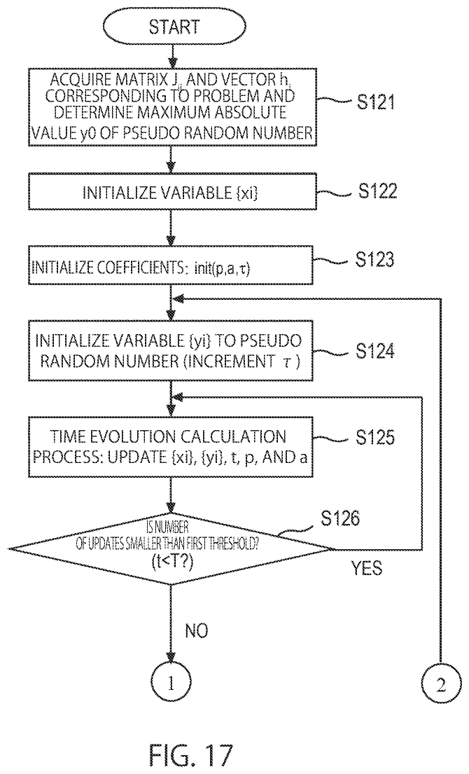

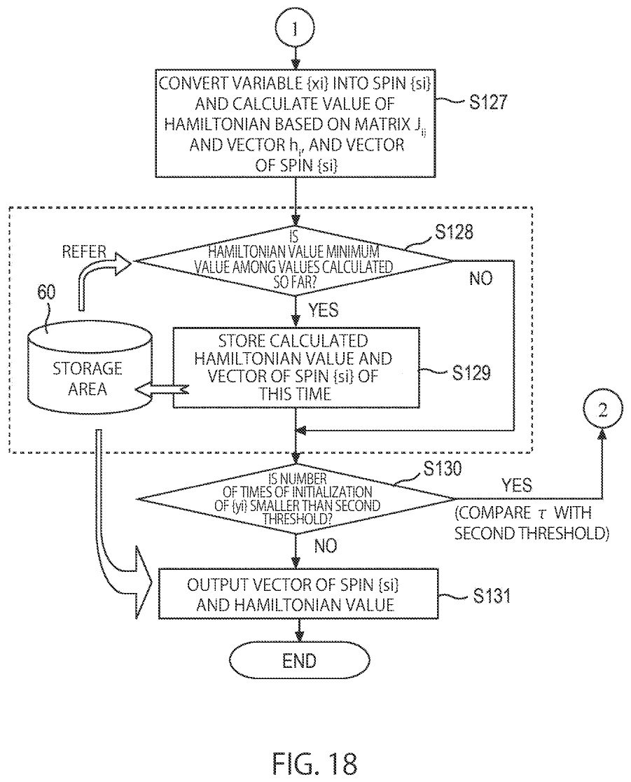

Flowcharts in FIGS. 17 and 18 illustrate an example of an algorithm according to a third modified example. Hereinafter, processing will be described with reference to FIGS. 17 and 18. Here, the first variable xᵢ is an element of the first vector, and the second variable yᵢ is an element of the second vector.

First, the calculation server acquires the matrix Jᵢⱼ and the vector hᵢ corresponding to a problem from the management server 1, and determines a maximum absolute value y0 of the pseudo random number (step S121). For example, when y0=0.1 is set, a pseudo random number of (−0.1, +0.1) is generated. However, the set value of y0 may be different from this. For example, the set value of y0 can be increased when it is desired to increase the change amount of the first variable xᵢ after the initialization of the second variable yᵢ. In addition, the set value of y0 can be decreased when it is desired to suppress the change amount of the first variable xᵢ after the initialization of the second variable yᵢ. Note that a seed s0 of the pseudo random number may be determined at the timing of step S121. The seed s0 of the pseudo random number may be an automatically determined value or a value designated by the user.

Next, the calculation server initializes the first variable x, (step S122). For example, xᵢ may be initialized to a pseudo random number. In addition, xᵢ may be initialized to 0, and a method for initializing xᵢ is not limited. Then, the calculation server initializes coefficients p(t), a(t), and τ (step S123). In addition, the variable t may be initialized in step S123. For example, the values of p, a, τ, and t can be set to 0 in step S123, but the initial values of p, a, τ, and t are not limited.

Next, the calculation server initializes the second variable yᵢ using a pseudo random number (step S124). Note that the calculation server may increment the counter variable τ in step S124 in order to perform a determination process in step S130 to be described later. As a result, the number of times of initialization of the second variable y, can be counted. In addition, the counter variable t may be initialized in step S124 in a case where the counter variable t is used in determination in step S 126 to be described later. For example, the value of t can be set to 0.

Then, the calculation server executes a time evolution calculation process, and updates the first variable xᵢ, the second variable yᵢ, the coefficient p, and the coefficient a (step S125). For example, the calculation server can execute the processes corresponding to steps S104 to S107 in FIG. 6 in step S125. In addition, the calculation server may execute the processing corresponding to FIG. 9 or 10 in step S125. When the variable t is used, for example, Δt may be added to t.

Next, the calculation server determines whether the number of updates of the first vector and the second vector is smaller than a first threshold (step S126). When the number of updates is smaller than the first threshold (YES in step S126), the calculation server executes the process in step S125 again. When the number of updates is equal to or larger than the first threshold (NO in step S126), the calculation server converts the first variable xᵢ into spin sᵢ, and calculates a value of the Hamiltonian based on the matrix Jᵢⱼ, the vector hᵢ, and the spin sᵢ (step S127). For example, the value of the Hamiltonian can be calculated based on (1).

Then, the calculation server refers to a storage area 60 and determines whether the Hamiltonian value calculated in the previous step is the minimum value among values calculated so far (step S128). When the value of the Hamiltonian calculated in the previous step is the minimum value among the values calculated so far (YES in step S128), the calculation server stores the calculated Hamiltonian value and the vector (solution vector) of the spin sᵢ at this time in the storage area 60 (step S129). In step S129, the calculation server may store the first vector in the storage area 60. As the storage area 60, a storage area of the shared memory 32 or the storage 34 can be used. In addition, a storage device outside the calculation server or a storage area of a cloud storage may be used as the storage area 60. However, a location of the storage area 60 is not limited. Note that the calculation server may skip the determination in step S128 and execute the process in step S129 when the storage area 60 is sufficiently large. The calculation server proceeds to the process in step S130 after executing the process in step S129.

If the Hamiltonian value calculated in step S127 is not the minimum value among the values calculated so far (NO in step S128), the calculation server skips the process in step S129 and proceeds to the process in step S130.

In step S130, the calculation server determines whether the number of times of initialization of the second variable yᵢ is smaller than the second threshold. The value of the counter variable τ may be compared with the second threshold in step S130. When the number of times of initialization of the second variable yᵢ is smaller than the second threshold (YES in step S130), the calculation server executes the processes of step S124 and the subsequent steps again. That is, the calculation server initializes the second variable yᵢ using the pseudo random number (step S124), and then executes the time evolution calculation process (step S125).

When the number of times of initialization of the second variable yᵢ is equal to or larger than the threshold (NO in step S130), the calculation server refers to the storage area 60 and outputs the vector of the spin sᵢ and the value of the Hamiltonian (step S131). In step S131, it is possible to output the solution vector closest to the optimal solution among the solution vectors obtained by the past iterations. In addition, when the first vector is stored in the storage area 60 in step S139, the calculation server may convert the first vector into the solution vector in step S161. For example, the calculation server may display the vector of the spin sᵢ and the value of the Hamiltonian on a screen of the client terminal 6. In addition, the calculation server may transfer the vector of the spin sᵢ and the value of the Hamiltonian to another information processing device.

It is possible to automatically select the first vector closest to the optimal solution based on the value of the Hamiltonian and to obtain the vector (solution vector) of the spin sᵢ based on the first vector by executing the processing in FIGS. 17 and 18. As a result, it is possible to search the wider range of the solution space and obtain the practical solution within the limited calculation time.

In the flowcharts of FIGS. 17 and 18, the energy function in (1) is used as the Hamiltonian. However, other formats of the Hamiltonian such as the Hamiltonian of (3) or the extended Hamiltonian of (4) may be used. Therefore, the process of converting the first vector into the solution vector may be skipped when parameters of the Hamiltonian are the first variable xᵢ and the second variable yᵢ.

As described above, the processing circuit of the information processing device may be configured to calculate the value of the Hamiltonian based on the first vector after repeating updating of the first vector and the second vector and repeat updating of the first vector and the second vector again after storing the first vector and the value of the Hamiltonian in the storage unit.

In addition, the processing circuit of the information processing device may be configured to repeat updating of the first vector and the second vector, then calculate a solution vector from the first vector by converting the first variable, which is a positive value, into a first value and converting the first variable, which is a negative value, into a second value smaller than the first value, calculate a value of a Hamiltonian (objective function) based on the solution vector, store the solution vector and the value of the Hamiltonian (objective function) in the storage unit, and then repeat updating of the first vector and the second vector.

### [Adjustment of Maximum Absolute Value of Pseudo Random Number]

The example in which the second variable y, is initialized using the pseudo random number has been described above. The information processing device and the information processing system may change a property of a pseudo random number to be used according to an iteration of loop processing. For example, the maximum absolute value of the pseudo random number to be generated can be set to a relatively large value in an iteration at an early stage. As a result, changes of the first variable xᵢ and the second variable yᵢ after the initialization of the second variable y, become large, and it becomes possible to search the wide range of the solution space. As a result, the probability of finding the optimal solution from the plurality of local solutions can be enhanced. For example, the maximum absolute value of the pseudo random number to be generated can be set to a relatively small value in an iteration at a late stage. As a result, the changes of the first variable xᵢ and the second variable yᵢ after initialization of the second variable yᵢ are suppressed. Therefore, in a case where the first vector has reached the vicinity of the optimal solution by a plurality of update processes, the first vector can be brought close to the optimal solution, and the accuracy of calculation can be improved.

Hereinafter, an example of processing in a case where the maximum absolute value of the pseudo random number to be used is changed depending on the iteration of the loop processing will be described.

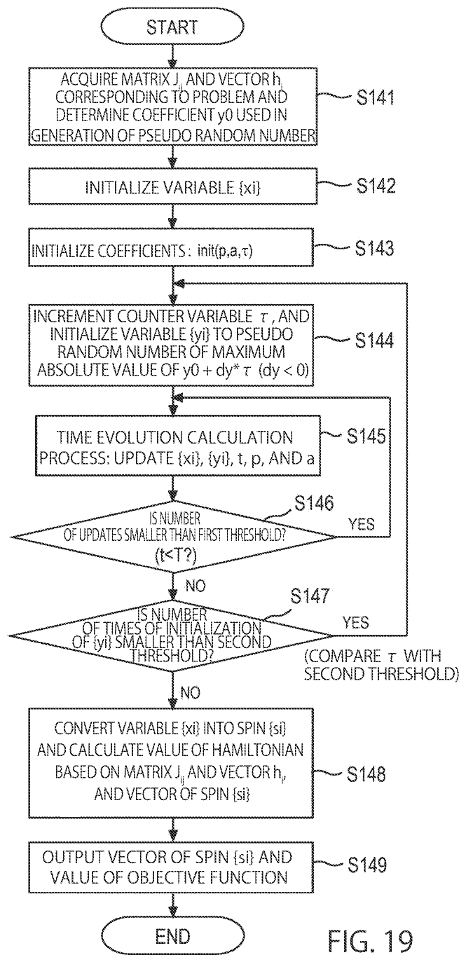

The flowchart of FIG. 19 illustrates an example of an algorithm according to a fourth modified example. Hereinafter, the processing will be described with reference to FIG. 19. Here, the first variable xᵢ is an element of the first vector, and the second variable yᵢ is an element of the second vector.

First, the calculation server acquires the matrix and the vector hᵢ corresponding to a problem from the management server 1, and determines the coefficient y0 to be used for generation of the pseudo random number (step S141). For example, when the maximum absolute value of the pseudo random number is set to 0.1, the pseudo random number of (−0.1, +0.1) is generated. For example, y0=0.1 can be set. However, the set value of y0 may be different from this. Note that a seed s0 of the pseudo random number may be determined at the timing of step S141. The seed s0 of the pseudo random number may be an automatically determined value or a value designated by the user.

Next, the calculation server initializes the first variable xᵢ (step S142). For example, xᵢ may be initialized to a pseudo random number. In addition, xᵢ may be initialized to 0, and a method for initializing xᵢ is not limited. Then, the calculation server initializes coefficients p(t), a(t), and τ (step S143). In addition, the variable t may be initialized in step S143. For example, the values of p, a, τ, and t can be set to 0 in step S143, but the initial values of p, a, τ, and t are not limited.

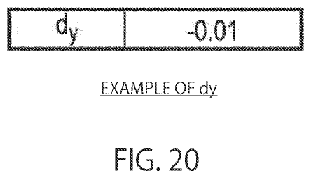

Next, the calculation server increments the counter variable τ and initializes the second variable yᵢ using the pseudo random number having the maximum absolute value of y0+dy×τ (step S144). A negative value can be used as dy. For example, dy may be set to −0.01 as illustrated in FIG. 20. The counter variable τ is used to count the number of times of initialization of the second variable yᵢ. Since the maximum absolute value of the pseudo random number is given as y0+dy×τ (dy<0), the maximum absolute value of the pseudo random number can be monotonically decreased if τ is incremented in each iteration of the loop processing. As a result, it is possible to perform calculation with high accuracy.

Then, the calculation server executes a time evolution calculation process, and updates the first variable xᵢ, the second variable yᵢ, the coefficient p, and the coefficient a (step S145). For example, the calculation server can execute the processes corresponding to steps S104 to S107 in FIG. 6 in step S145. In addition, the calculation server may execute the processing corresponding to FIG. 9 or 10 in step S145. When the variable t is used, for example, Δt may be added to t.

Next, the calculation server determines whether the number of updates of the first vector and the second vector is smaller than a first threshold (step S146). When the number of updates is smaller than the first threshold (YES in step S146), the calculation server executes the process in step S145 again. When the number of updates is equal to or larger than the first threshold (NO in step S146), the calculation server determines whether the number of times of initialization of the second variable yᵢ is smaller than a second threshold (step S147).

When the number of times of initialization of the second variable yᵢ is smaller than the second threshold (YES in step S147), the calculation server executes the processes of step S144 and the subsequent steps again. That is, the calculation server initializes the second variable yᵢ using the pseudo random number of the maximum absolute value of y0+dy×τ (step S144), and then executes the time evolution calculation process (step S145).

When the number of times of initialization of the second variable yᵢ is equal to or larger than the second threshold (NO in step S147), the calculation server converts the first variable xᵢ into spin sᵢ, and calculates a value of the Hamiltonian based on the matrix Jᵢⱼ, the vector hᵢ, and the spin sᵢ (step S148). For example, the value of the Hamiltonian can be calculated based on (1) in step S148. Then, the calculation server outputs the vector of the spin sᵢ and the value of the Hamiltonian (step S149). For example, the calculation server may display the vector of the spin sᵢ and the value of the Hamiltonian on a screen of the client terminal 6. In addition, the calculation server may transfer the vector of the spin sᵢ and the value of the Hamiltonian to another information processing device. Further, the calculation server may store the vector of the spin si and the value of the Hamiltonian in an external storage device or a storage of a cloud.

Note that the maximum absolute value of y0+dy×τ (dy<0) of the pseudo random number used in FIG. 19 is merely an example. Therefore, the maximum absolute value of the pseudo random number may be defined by a formula different from this.

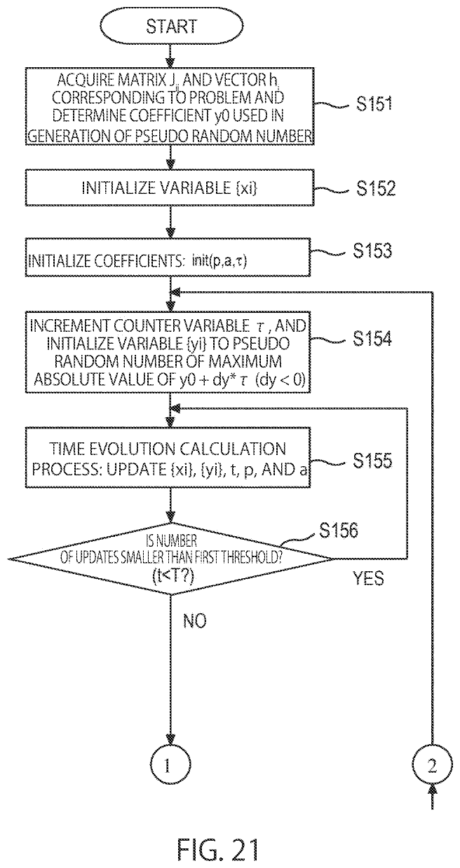

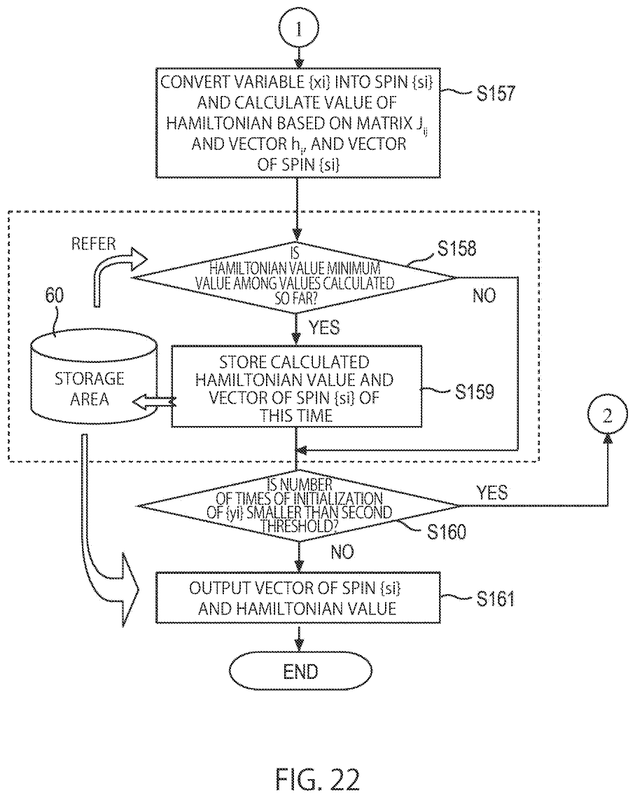

The information processing device and the information processing system may (1) adjust the maximum absolute value of the pseudo random number, and further (2) calculate the Hamiltonian a plurality of times and compare the Hamiltonian values as in flowcharts of FIGS. 21 and 22 which will be described later.

The flowcharts in FIGS. 21 and 22 illustrate an example of an algorithm according to a fifth modified example. Hereinafter, processing will be described with reference to FIGS. 21 and 22. Here, the first variable xᵢ is an element of the first vector, and the second variable yᵢ is an element of the second vector.

First, the calculation server acquires the matrix Jᵢⱼ and the vector hᵢ corresponding to a problem from the management server 1, and determines the coefficient y0 to be used for generation of the pseudo random number (step S151). For example, when the maximum absolute value of the pseudo random number is set to 0.1, the pseudo random number of (−0.1, +0.1) is generated. For example, y0=0.1 can be set. However, the set value of y0 may be different from this. Note that a seed s0 of the pseudo random number may be determined at the timing of step S151. The seed s0 of the pseudo random number may be an automatically determined value or a value designated by the user.

Next, the calculation server initializes the first variable xᵢ (step S152). For example, xᵢ may be initialized to a pseudo random number. In addition, xᵢ may be initialized to 0, and a method for initializing xᵢ is not limited. Then, the calculation server initializes coefficients p(t), a(t), and τ (step S153). In addition, the variable t may be initialized in step S153. For example, the values of p, a, τ, and t can be set to 0 in step S153, but the initial values of p, a, τ, and t are not limited.

Next, the calculation server increments the counter variable τ and initializes the second variable yᵢ using the pseudo random number having the maximum absolute value of y0+dy×τ (step S154). A negative value can be used as dy. For example, dy may be set to −0.01 as illustrated in FIG. 20. The counter variable τ is used to count the number of times of initialization of the second variable yᵢ. Since the maximum absolute value of the pseudo random number is given as y0+dy×τ (dy<0), the maximum absolute value of the pseudo random number can be monotonically decreased if τ is incremented in each iteration of the loop processing. As a result, the calculation accuracy can be improved.

Then, the calculation server executes a time evolution calculation process, and updates the first variable xᵢ, the second variable yᵢ, the coefficient p, and the coefficient a (step S155). For example, the calculation server can execute the processes corresponding to steps S104 to S107 in FIG. 6 in step S155. In addition, the calculation server may execute the processing corresponding to FIG. 9 or 10 in step S155. When the variable t is used, for example, Δt may be added to t.

Next, the calculation server determines whether the number of updates of the first vector and the second vector is smaller than a first threshold (step S156). When the number of updates is smaller than the first threshold (YES in step S156), the calculation server executes the process in step S155 again. When the number of updates is equal to or larger than the first threshold (NO in step S156), the calculation server converts the first variable xᵢ into spin sᵢ, and calculates a value of the Hamiltonian based on the matrix Jᵢⱼ, the vector hᵢ, and the spin sᵢ (step S157). For example, the value of the Hamiltonian can be calculated based on (1).

Then, the calculation server refers to a storage area 60 and determines whether the Hamiltonian value calculated in the previous step is the minimum value among values calculated so far (step S158). When the value of the Hamiltonian calculated in the previous step is the minimum value among the values calculated so far (YES in step S158), the calculation server stores the calculated Hamiltonian value and the vector (solution vector) of the spin sᵢ at this time in the storage area 60 (step S159). In step S159, the calculation server may store the first vector in the storage area 60. As the storage area 60, a storage area of the shared memory 32 or the storage 34 can be used. In addition, a storage device outside the calculation server or a storage area of a cloud storage may be used as the storage area 60. However, a location of the storage area 60 is not limited. Note that the calculation server may skip the determination in step S158 and execute the process in step S159 when the storage area 60 is sufficiently large. The calculation server proceeds to the process in step S160 after executing the process in step S159.

If the Hamiltonian value calculated in step S157 is not the minimum value among the values calculated so far (NO in step S158), the calculation server skips the process in step S159 and proceeds to the process in step S160.

In step S160, the calculation server determines whether the number of times of initialization of the second variable yᵢ is smaller than the second threshold. The value of the counter variable τ may be compared with the second threshold in step S160. When the number of times of initialization of the second variable yᵢ is smaller than the second threshold (YES in step S160), the calculation server executes the processes of step S154 and the subsequent steps again. That is, the calculation server initializes the second variable yᵢ using the pseudo random number of the maximum absolute value of y0+dy×τ (step S154), and then executes the time evolution calculation process (step S155).

When the number of times of initialization of the second variable yᵢ is equal to or larger than the threshold (NO in step S160), the calculation server refers to the storage area 60 and outputs the vector of the spin sᵢ and the value of the Hamiltonian (step S161). In step S161, it is possible to output the solution vector closest to the optimal solution among the solution vectors obtained by the past iterations. In addition, when the first vector is stored in the storage area 60 in step S159, the calculation server may convert the first vector into the solution vector in step S161. For example, the calculation server may display the vector of the spin sᵢ and the value of the Hamiltonian on a screen of the client terminal 6. In addition, the calculation server may transfer the vector of the spin sᵢ and the value of the Hamiltonian to another information processing device.

It is possible to automatically select the first vector closest to the optimal solution based on the value of the Hamiltonian and to obtain the vector (solution vector) of the spin sᵢ based on the first vector by executing the processing in FIGS. 21 and 22. As a result, it is possible to search the wider range of the solution space and obtain the practical solution within the limited calculation time. In addition, the accuracy of calculation can be improved by adjusting the maximum absolute value of the pseudo random number.

In the flowcharts of FIGS. 21 and 22, the energy function in (1) is used as the Hamiltonian. However, other formats of the Hamiltonian such as the Hamiltonian of (3) or the extended Hamiltonian of (4) may be used. Therefore, the process of converting the first vector into the solution vector may be skipped when parameters of the Hamiltonian are the first variable xᵢ and the second variable yᵢ.

As described above, the processing circuit of the information processing device may be configured to change the maximum absolute value of the pseudo random number depending on the number of times of initialization of the second variable of the second vector. In addition, the processing circuit of the information processing device may be configured to monotonically decrease the maximum absolute value of the pseudo random number depending on the number of times of initialization of the second variable of the second vector. Here, the process of changing the maximum absolute value of the pseudo random number according to the iteration in the loop processing has been described as an example. However, the property of the generated pseudo random number may be changed by a method different from this. For example, a type of algorithm used to generate the pseudo random number may be changed according to an iteration. In addition, a value of a seed used for generation of the pseudo random number may be changed according to an iteration.

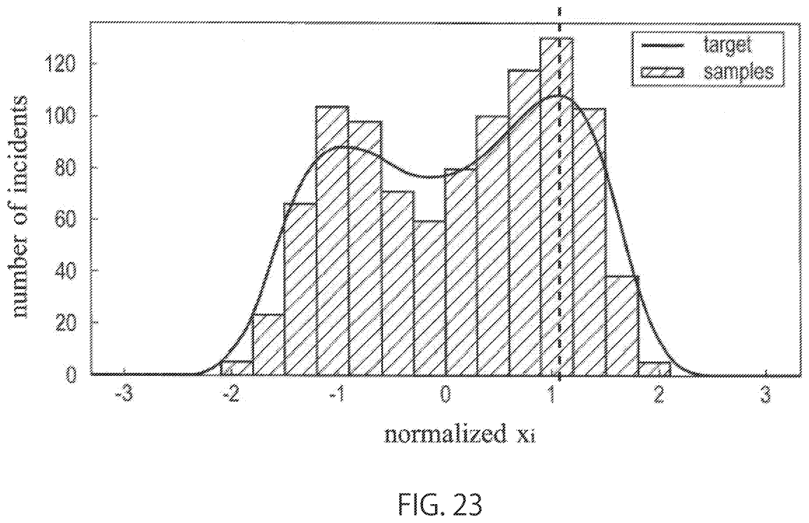

A graph of FIG. 23 illustrates an example of a result in a case where calculation is performed according to the algorithm of FIG. 6. The horizontal axis in FIG. 23 represents a value of the normalized first variable xᵢ. On the other hand, the vertical axis (height of a bar graph) in FIG. 23 represents the frequency at which the first variable xᵢ takes a value of each range after calculation. In FIG. 23, a curve drawn by a solid line corresponds to a value of the Hamiltonian. In the graph of FIG. 23, the maximum peak of this curve corresponds to an optimal solution. In FIG. 23, a value of the first variable xᵢ corresponding to the optimal solution is indicated by a broken line. In the example of FIG. 23, the vicinity of “normalized xᵢ” =1 corresponds to the optimal solution.

In the example of FIG. 23, the frequency at which the value of the first variable xᵢ is in a range not including the optimal solution (range not including the broken line) after the calculation is high. Therefore, the probability that the optimal solution can be obtained by the calculation process is not sufficiently high. In such a case, it is necessary to repeat the calculation process a plurality of times in order to obtain a practical solution. In solving the combinatorial optimization problem, it is desirable to obtain the practical solution with a shorter calculation time.

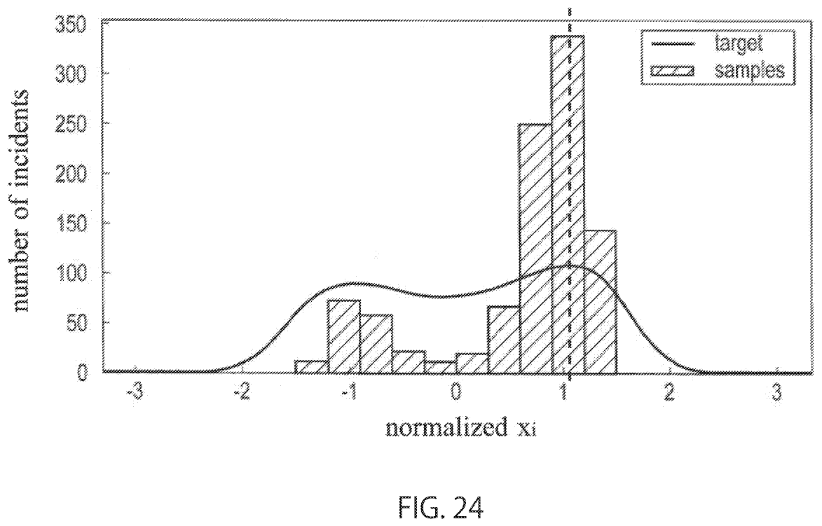

A graph of FIG. 24 illustrates an example of a result in a case where calculation is performed according to the algorithm of FIG. 7. Even in FIG. 24, a curve drawn by a solid line corresponds to a value of the Hamiltonian, and the maximum peak of the curve corresponds to the optimal solution. In addition, a value of the first variable xᵢ corresponding to the optimal solution is also indicated by a broken line in FIG. 24.

In the example of FIG. 24, the frequency at which the value of the first variable xᵢ enters a range including the optimal solution (range including the broken line) after the calculation is higher than the frequency at which the value of the first variable xᵢ enters the other ranges. Therefore, the probability that the optimal solution can be obtained by the calculation process is higher than that in the example of FIG. 23. Therefore, the practical solution of the combinatorial optimization problem can be obtained with a shorter calculation time than that in the example of FIG. 23.

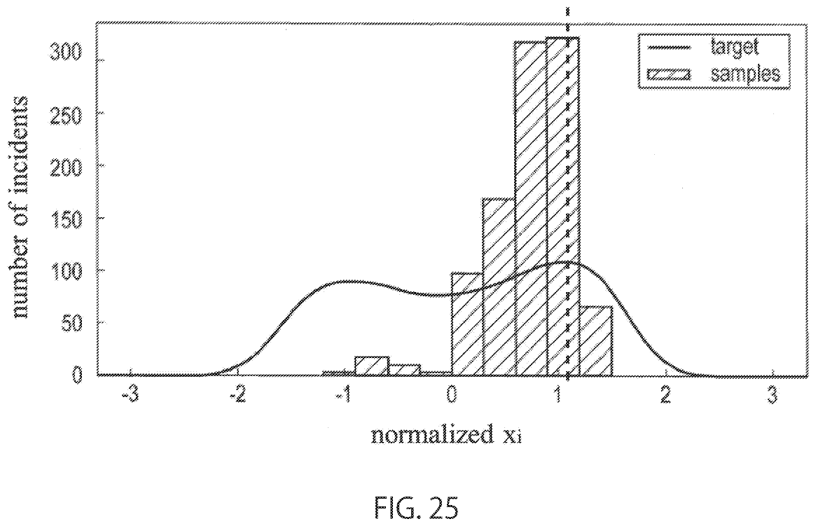

A graph of FIG. 25 illustrates an example of a result in a case where calculation is performed according to the algorithm of FIGS. 17 and 18. Even in FIG. 25, a curve drawn by a solid line corresponds to a value of the Hamiltonian, and the maximum peak of the curve corresponds to the optimal solution. In addition, a value of the first variable xᵢ corresponding to the optimal solution is also indicated by a broken line in FIG. 25.

Even in the example of FIG. 25, the frequency at which the value of the first variable xᵢ enters a range including the optimal solution (range including the broken line) after the calculation is higher than the frequency at which the value of the first variable xᵢ enters the other ranges. Therefore, the optimal solution can be obtained with a higher probability as compared with the example of FIG. 23. Therefore, the practical solution of the combinatorial optimization problem can be obtained with a shorter calculation time than that in the example of FIG. 23.

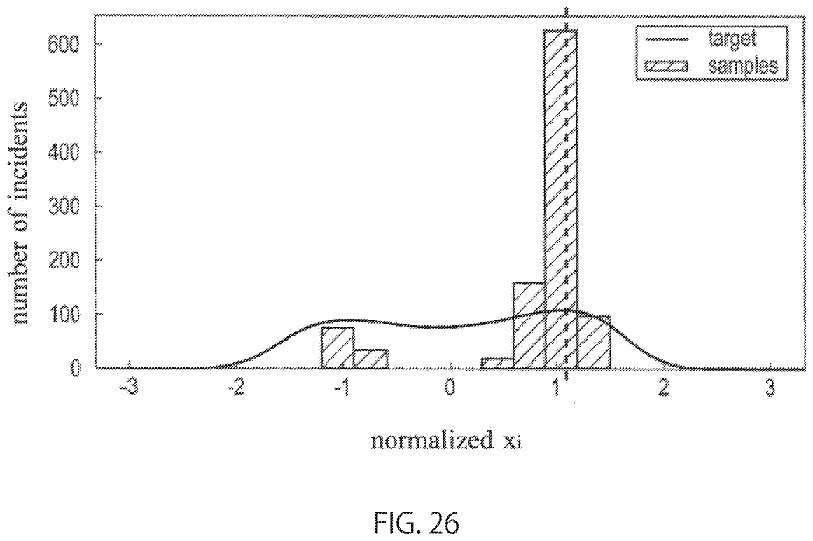

A graph of FIG. 26 illustrates an example of a result in a case where calculation is performed according to the algorithm of FIGS. 21 and 22. Even in FIG. 26, a curve drawn by a solid line corresponds to a value of the Hamiltonian, and the maximum peak of the curve corresponds to the optimal solution. In addition, a value of the first variable xᵢ corresponding to the optimal solution is also indicated by a broken line in FIG. 26.

In the example of FIG. 26, the frequency at which the value of the first variable xᵢ enters a range including the optimal solution (range including the broken line) after the calculation is significantly higher than the frequency at which the value of the first variable x, enters the other ranges. Therefore, the optimal solution can be obtained with a higher probability as compared with the examples of FIGS. 23 to 25. Therefore, in the example of FIG. 26, it is possible to obtain the practical solution of the combinatorial optimization problem with the shortest calculation time among the examples of FIGS. 23 to 26.

In the information processing device and the information processing system according to the present embodiment, the second variable yᵢ is initialized a plurality of times using the pseudo random number, so that the solution can be searched for in the wider region of the solution space regardless of the number of local solutions. As a result, it is possible to enhance the probability of obtaining the optimal solution or the approximate solution close thereto. In addition, in a case where the optimal solution or the approximate solution close thereto is reached in the middle of the calculation process, it is possible to detect such a fact without a miss by calculating the value of the Hamiltonian in the loop processing. As a result, it is possible to provide the user with the information processing device or the information processing system that calculates the solution of the combinatorial optimization problem within a practical time.

Examples of the information processing system, the information processing method, the storage medium, and the program will be described hereinafter.

The information processing system may be configured to repeatedly update a first vector which has a first variable as an element and a second vector which has a second variable corresponding to the first variable as an element. The information processing system may include a storage device and an information processing device. The storage device is configured to store the first variable and the second variable. The information processing device updates the first vector by performing weighted addition of the corresponding second variable to the first variable. In addition, the information processing device updates the second vector by weighting the first variable with the first coefficient that monotonically increases or monotonically decreases depending on the number of times of update, adding the weighted first variable to the corresponding second variable, calculating a problem term using the plurality of first variables, and adding the problem term to the second variable. Further, the information processing device repeats updating of the first vector and the second vector, then initializes the second variable of the second vector using the pseudo random number, and repeats updating of the first vector and the second vector again.

The information processing method may repeatedly update a first vector which has a first variable as an element and a second vector which has a second variable corresponding to the first variable as an element. Here, the information processing method may include: a step of updating the first vector by weighted addition of the corresponding second variable to the first variable; and a step of updating the second vector by weighting the first variable with a first coefficient that monotonically increases or monotonically decreases depending on the number of updates, adding the weighted first variable to the corresponding second variable, calculating a problem term using the plurality of first variables, and adding the problem term to the second variable. In addition, the information processing method may repeat updating of the first vector and the second vector, then initialize the second variable of the second vector using the pseudo random number, and repeat updating of the first vector and the second vector again.

The program may cause a computer to repeatedly update a first vector which has a first variable as an element and a second vector which has a second variable corresponding to the first variable as an element. Here, the program may include: a step of updating the first vector by weighted addition of the corresponding second variable to the first variable; and a step of updating the second vector by weighting the first variable with a first coefficient that monotonically increases or monotonically decreases depending on the number of updates, adding the weighted first variable to the corresponding second variable, calculating a problem term using the plurality of first variables, and adding the problem term to the second variable. In addition, the program may cause the computer to execute a process of repeating updating of the first vector and the second vector, then initializing the second variable of the second vector using the pseudo random number, and repeating updating of the first vector and the second vector again. In addition, a non-transitory computer-readable storage medium may store the above-described program.

### [Calculation Including Term of Many-Body Interaction]

It is also possible to solve a combinatorial optimization problem having a third-order or higher-order objective function by using the simulated bifurcation algorithm. A problem of obtaining a combination of variables that minimizes the third-order or higher-order objective function, which has a binary variable as a variable, is called a higher-order binary optimization (HOBO) problem. In a case of handling the HOBO problem, the following Formula (7) can be used as an energy formula in an Ising model extended to the higher order.

$$[ Formula 7 ]$$

$${E}_{HOBO} = {\sum }_{i = 1}^{N} {J}_{i}^{( 1 )} {s}_{i} + \frac{1}{2} {\sum }_{i = 1}^{N} {\sum }_{j = 1}^{N} {J}_{i , j}^{( 2 )} {s}_{i} {s}_{j} + \frac{1}{3 !} {\sum }_{i = 1}^{N} {\sum }_{j = 1}^{N} {\sum }_{k = 1}^{N} {J}_{i , j , k}^{( 3 )} {s}_{i} {s}_{j} {s}_{k} + ⋯ \qquad ( 7 )$$

Here, J⁽ⁿ⁾ is an n-rank tensor, and is obtained by generalizing the matrix J of the local magnetic field hᵢ and a coupling coefficient of Formula (1). For example, a tensor J⁽¹⁾ corresponds to a vector of the local magnetic field hᵢ. In the n-rank tensors J⁽ⁿ⁾, when a plurality of indices have the same value, values of elements are 0. Although terms up to a third-order term are illustrated in Formula (7), but a higher-order term can also be defined in the same manner as in Formula (7). Formula (7) corresponds to the energy of the Ising model including a many-body interaction.

Note that both QUBO and HOBO can be said to be a type of polynomial unconstrained binary optimization (PUBO). That is, a combinatorial optimization problem having a second-order objective function in PUBO is QUBO. In addition, it can be said that a combinatorial optimization problem having a third-order or higher-order objective function in PUBO is HOBO.

In a case where the HOBO problem is solved using the simulated bifurcation algorithm, the Hamiltonian H of Formula (3) described above may be replaced with the Hamiltonian H of the following Formula (8).

$$[ Formula 8 ]$$

$$H = {\sum }_{i = 1}^{N} [ \frac{D}{2} ( {x}_{i}^{2} + {y}_{i}^{2} ) - \frac{p ( t )}{2} {x}_{i}^{2} + \frac{K}{4} {x}_{i}^{4} + c ( {J}_{i}^{( 1 )} {x}_{i} α ( t ) + \frac{1}{2} {\sum }_{j = 1}^{N} {J}_{i . j}^{( 2 )} {x}_{i} {x}_{j} + \frac{1}{3 !} {\sum }_{j = 1}^{N} {\sum }_{k = 1}^{N} {J}_{i , j , k}^{( 3 )} {x}_{i} {x}_{j} {x}_{k} + ⋯ ) ] \\ {H}_{Ising} = {\sum }_{i = 1}^{N} [ {J}_{i}^{( 1 )} {x}_{i} α ( t ) + \frac{1}{2} {\sum }_{j = 1}^{N} {J}_{i , j}^{( 2 )} {x}_{i} {x}_{j} + \frac{1}{3 !} {\sum }_{j = 1}^{N} {\sum }_{k = 1}^{N} {J}_{i , j , k}^{( 3 )} {x}_{i} {x}_{j} {x}_{k} + ⋯ ] \qquad ( 8 )$$

In addition, a problem term is derived from Formula (8) using a plurality of first variables expressed in the following Formula (9).

$$[ Formula 9 ]$$

$${z}_{i} = \frac{\partial {H}_{Ising}}{\partial {x}_{i}} = {J}_{i}^{( 1 )} α ( t ) + {\sum }_{j = 1}^{N} {J}_{i . j}^{( 2 )} {x}_{j} + {\sum }_{j = 1}^{N} {\sum }_{k = 1}^{N} {J}_{i , j , k}^{( 3 )} {x}_{j} {x}_{k} + ⋯ \qquad ( 9 )$$

The problem term zᵢ of (9) takes a format in which the second expression of (8) is partially differentiated with respect to any variable xᵢ (element of the first vector). The partially differentiated variable xᵢ differs depending on an index i. Here, the index i of the variable xᵢ corresponds to an index designating an element of the first vector and an element of the second vector.

In a case where calculation including the term of the many-body interaction is performed, the recurrence formula of (6) described above is replaced with the following recurrence formula of (10).

$$[ Formula 10 ]$$

$${x}_{i} ( t + Δ t ) = {x}_{i} ( t ) + {Dy}_{i} ( t ) Δ t \\ {y}_{i} ( t + Δ t ) = {y}_{i} ( t ) + [ \{ - D + {p}^{( m 1 )} ( t + Δ t ) - {Kx}_{i}^{2} \} {x}_{i} ( t + Δ t ) ] Δ t - c Δ t ( {J}_{i}^{( 1 )} α ( t + Δ t ) + {\sum }_{j = 1}^{N} {J}_{i . j}^{( 2 )} {x}_{j} ( t + Δ t ) + {\sum }_{j = 1}^{N} {\sum }_{k = 1}^{N} {J}_{i , j , k}^{( 3 )} {x}_{j} ( t + Δ t ) {x}_{k} ( t + Δ t ) + ⋯ ) \qquad ( 10 )$$

(10) corresponds to a further generalized recurrence formula of (6).

The problem terms described above are merely examples of a problem term that can be used by the information processing device according to the present embodiment. Therefore, a format of the problem term used in the calculation may be different from these.

### MODIFIED EXAMPLE OF ALGORITHM

Here, a modified example of the simulated bifurcation algorithm will be described. For example, various modifications may be made to the above-described simulated bifurcation algorithm for the purpose of reducing an error or reducing a calculation time.

For example, additional processing may be executed at the time of updating a first variable in order to reduce the error in calculation. For example, when an absolute value of the first variable xᵢ becomes larger than 1 by the update, the value of the first variable xᵢ is replaced with sgn(xᵢ). That is, when xᵢ>1 is satisfied by the update, the value of the variable xᵢ is set to 1. In addition, when xᵢ<−1 is satisfied by the update, the value of the variable xᵢ is set to −1. As a result, it is possible to approximate the spin sᵢ with higher accuracy using the variable xᵢ. Since such processing is included, the algorithm is equivalent to a physical model of an N particles having a wall at positions of xᵢ=±1. More generally speaking, an arithmetic circuit may be configured to set the first variable, which has a value smaller than a second value, to the second value, and set the first variable, which has a value larger than a first value, to the first value.

Further, when xᵢ>1 is satisfied by the update, the variable yᵢ corresponding to the variable xᵢ may be multiplied by a coefficient rf. For example, when the coefficient rf of −1<r≤0 is used, the above wall becomes a wall of the reflection coefficient rf. In particular, when the coefficient rf of rf=0 is used, the algorithm is equivalent to a physics model with a wall causing completely inelastic collisions at positions of xᵢ=±1. More generally speaking, the arithmetic circuit may be configured to update a second variable which corresponds to the first variable having the value smaller than the first value or a second variable which corresponds to the first variable larger than the second value, to a value obtained by multiplying the original second variable by a second coefficient. For example, the arithmetic circuit may be configured to update the second variable which corresponds to the first variable having the value smaller than −1 or the second variable which corresponds to the first variable having the value larger than 1, to the value obtained by multiplying the original second variable by the second coefficient. Here, the second coefficient corresponds to the above-described coefficient rf.

Note that the arithmetic circuit may set a value of the variable yᵢ corresponding to the variable xᵢ to a pseudo random number when xᵢ>1 is satisfied by the update. For example, a random number in the range of [−0.1, 0.1] can be used. That is, the arithmetic circuit may be configured to set a value of the second variable which corresponds to a first variable having the value smaller than the second value or a value of the second variable which corresponds to the first variable having the value larger than the first value, to the pseudo random number.

If the update process is executed so as to suppress |xᵢ|>1 as described above, the value of x, does not diverge even if the non-linear term K×xᵢ² in (6) and (10) is removed. Therefore, it is possible to use an algorithm illustrated in (11) below.

$$[ Formula 11 ]$$

$${x}_{i} ( t + Δ t ) = {x}_{i} ( t ) + {Dy}_{i} ( t ) Δ t \\ {y}_{i} ( t + Δ t ) = {y}_{i} ( t ) + [ \{ - D + {p}^{( m 1 )} ( t + Δ t ) \} {x}_{i} ( t + Δ t ) ] Δ t - c Δ t ( {J}_{i}^{( 1 )} α ( t + Δ t ) + {\sum }_{j = 1}^{N} {J}_{i . j}^{( 2 )} {x}_{j} ( t + Δ t ) + {\sum }_{j = 1}^{N} {\sum }_{k = 1}^{N} {J}_{i , j , k}^{( 3 )} {x}_{j} ( t + Δ t ) {x}_{k} ( t + Δ t ) + ⋯ ) \qquad ( 11 )$$

In the algorithm of (11), a continuous variable x is used in the problem term instead of a discrete variable. Therefore, there is a possibility that an error from the discrete variable used in the original combinatorial optimization problem occurs. In order to reduce this error, a value sgn(x) obtained by converting the continuous variable x by a signum function can be used instead of the continuous variable x in the calculation of the problem term as in (12) below.

$$[ Formula 12 ]$$

$${x}_{i} ( t + Δ t ) = {x}_{i} ( t ) + {Dy}_{i} ( t ) Δ t \\ {y}_{i} ( t + Δ t ) = {y}_{i} ( t ) + [ \{ - D + {p}^{( m 1 )} ( t + Δ t ) \} {x}_{i} ( t + Δ t ) ] Δ t - c Δ t ( {J}_{i}^{( 1 )} α ( t + Δ t ) + {\sum }_{j = 1}^{N} {J}_{i . j}^{( 2 )} sgn ( {x}_{j} ( t + Δ t ) ) + {\sum }_{j = 1}^{N} {\sum }_{k = 1}^{N} {J}_{i , j , k}^{( 3 )} sgn ( {x}_{j} ( t + Δ t ) ) sgn ( {x}_{k} ( t + Δ t ) ) + ⋯ ) \qquad ( 12 )$$

In (12), sgn(x) corresponds to the spin s.

In (12), the coefficient α of a term including the first-rank tensor in the problem term may be a constant (for example, α=1). In an algorithm of (12), the product of spins appearing in the problem term always takes any value of −1 or 1, and thus, it is possible to prevent the occurrence of an error due to the product operation when the HOMO problem having the higher-order objective function is handled. As in the algorithm of (12) described above, data calculated by the calculation server may further include a spin vector (s₁, s₂, s_{N}) having the variable sᵢ (i=1, 2, . . . , N) as an element. The spin vector can be obtained by converting each element of the first vector by a signum function.

### [Example of Parallelization of Variable Update Processes]

Hereinafter, an example of parallelization of variable update processes at the time of calculation of the simulated bifurcation algorithm will be described.

First, an example in which the simulated bifurcation algorithm is implemented in a PC cluster will be described. The PC cluster is a system that connects a plurality of computers and realizes calculation performance that is not obtainable by one computer. For example, the information processing system 100 illustrated in FIG. 1 includes a plurality of calculation servers and processors, and can be used as the PC cluster. For example, the parallel calculation can be executed even in a configuration in which memories are arranged to be distributed in a plurality of calculation servers as in the information processing system 100 by using a message passing interface (MPI) in the PC cluster. For example, the control program 14E of the management server 1, the calculation program 34B and the control program 34C of each of the calculation servers can be implemented using the MPI.

In a case where the number of processors used in the PC cluster is Q, it is possible to cause each of the processors to calculate L variables among the variables xᵢ included in the first vector (x₁, x₂, . . . , x_{N}). Similarly, it is possible to cause each of the processors to calculate L variables among the variables yᵢ included in the second vector (y₁, y₂, y_{N}). That is, processors #j (j=1, 2, . . . , Q) calculate variables {xₘ|m=(j−1)L+1, (j−1)L+2, . . . , jL} and {yₘ|m=(j−1)L+1, (j−1)L+2, . . . , jL}. In addition, a tensor J⁽ⁿ⁾ expressed in the following (13), necessary for the calculation of {yₘ|m=(j−1)L+1, (j−1)L+2, . . . , jL} by the processors #j, is stored in a storage area (for example, a register, a cache, a memory, or the like) accessible by the processors #j.

$$[ Formula 13 ]$$

$$\{ {J}_{m}^{( 1 )} \vert m = ( i - 1 ) L + 1 , … iL \} \\ \{ {J}_{m , j}^{( 2 )} \vert m = ( i - 1 ) L + 1 , … iL ; j = 1 , … N \} \\ \{ {J}_{m . j , k}^{( 3 )} \vert m = ( i - 1 ) L + 1 , … iL ; j = 1 , … N ; k = 1 , … N \} , … \qquad ( 13 )$$

Here, the case where each of the processors calculates the constant number of variables of each of the first vector and the second vector has been described. However, the number of elements (variables) of each of the first vector and the second vector to be calculated may be different depending on a processor. For example, in a case where there is a performance difference depending on a processor implemented in a calculation server, the number of variables to be calculated can be determined depending on the performance of the processor.

Values of all the components of the first vector (x₁, x₂, . . . , x_{N}) are required in order to update the value of the variable yᵢ. The conversion into a binary variable can be performed, for example, by using the signum function sgn( ). Therefore, the values of all the components of the first vector (x₁, x₂, . . . , x_{N}) can be shared by the Q processors using the Allgather function. Although it is necessary to share the values between the processors regarding the first vector (x₁, x₂, . . . , x_{N}), but it is not essential to share values between the processors regarding the second vector (y₁, y₂, . . . , y_{N}) and the tensor J⁽ⁿ⁾. The sharing of data between the processors can be realized, for example, by using inter-processor communication or by storing data in a shared memory.

The processor #j calculates a value of the problem term {zₘ|m=(j−1)L+1, (j−1)L+2, . . . , jL}. Then, the processor #j updates the variable {yₘ|m=(j−1)L+1, (j−1)L+2, . . . , jL} based on the calculated value of the problem term {{zₘ|m=(j−1)L+1, (j−1)L+2, . . . , jL}.

As illustrated in the above-described respective formulas, the calculation of the vector (z₁, z₂, . . . , z_{N}) of the problem term requires the product-sum operation including the calculation of the product of the tensor J⁽ⁿ⁾ and the vector (x₁, x₂, . . . , x_{N}). The product-sum operation is processing with the largest calculation amount in the above-described algorithm, and can be a bottleneck in improving the calculation speed. Therefore, the product-sum operation is distributed to Q=N/L processors and executed in parallel in the implementation of the PC cluster, so that the calculation time can be shortened.

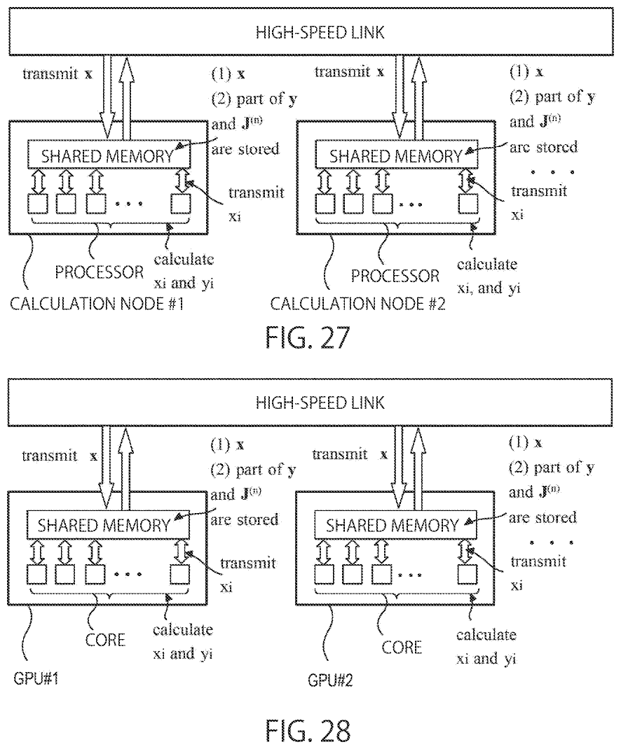

FIG. 27 schematically illustrates an example of a multi-processor configuration. A plurality of calculation nodes in FIG. 27 correspond to, for example, the plurality of calculation servers of the information processing system 100. In addition, a high-speed link of FIG. 27 corresponds to, for example, the interconnection between the calculation servers formed by the cables 4a to 4c and the switch 5 of the information processing system 100. A shared memory in FIG. 27 corresponds to, for example, the shared memory 32. Processors in FIG. 27 correspond to, for example, the processors 33A to 33D of the respective calculation servers. Note that FIG. 27 illustrates the plurality of calculation nodes, but the use of a configuration of a single calculation node is not precluded.

FIG. 27 illustrates data arranged in each of components and data transferred between the components. In each of the processors, values of the variables xᵢ and yᵢ are calculated. In addition, the variable xᵢ is transferred between the processor and the shared memory. In the shared memory of each of the calculation nodes, for example, the first vector (x₁, x₂, . . . , x_{N})), L variables of the second vector (y₁, y₂, . . . , y_{N}), and some of the tensors J⁽ⁿ⁾ are stored. Then, for example, the first vector (x₁, x₂, . . . , x_{N}) is transferred in the high-speed link connecting the calculation nodes. In a case where the Allgather function is used, all elements of the first vector (x₁, x₂, . . . , x_{N}) are required in order to update the variable y, in each of the processors.

Note that the arrangement and transfer of data illustrated in FIG. 27 are merely examples. A data arrangement method, a transfer method, and a parallelization method in the PC cluster are not particularly limited.

In addition, the simulated bifurcation algorithm may be calculated using a graphics processing unit (GPU).

FIG. 28 schematically illustrates an example of a configuration using the GPU. FIG. 28 illustrates a plurality of GPUs connected to each other by a high-speed link. Each GPU is equipped with a plurality of cores capable of accessing a shared memory. In addition, the plurality of GPUs are connected via the high-speed link to form a GPU cluster in the configuration example of FIG. 28. For example, if the GPUs are mounted on the respective calculation servers in FIG. 1, the high-speed link corresponds to the interconnection between the calculation servers formed by the cables 4a to 4c and the switch 5. Note that the plurality of GPUs are used in the configuration example of FIG. 28, but parallel calculation can be executed even in a case where one GPU is used. That is, each of the GPUs of FIG. 28 may perform the calculation corresponding to each of the calculation nodes of FIG. 16. That is, the processor (processing circuit) of the information processing device (calculation server) may be a core of the graphics processing unit (GPU).

In the GPU, the variables xᵢ and yᵢ and the tensor J⁽ⁿ⁾ are defined as device variables. The GPUs can calculate the product of the tensor J⁽ⁿ⁾ necessary to update the variable yᵢ and the first vector (x₁, x₂, . . . , x_{N}) in parallel by a matrix vector product function. Note that the product of the tensor and the vector can be obtained by repeatedly executing the matrix vector product operation. In addition, it is possible to parallelize the processes by causing each thread to execute a process of updating the i-th element (xᵢ, yᵢ) for a portion other than the product-sum operation in the calculation of the first vector (x₁, x₂, . . . , x_{N}) and the second vector (y₁, y₂, . . . , y_{N}).

The information processing device may include a plurality of processing circuits. In this case, the respective processing circuits may be configured to update at least a part of the first vector and at least a part of the second vector in parallel.

In addition, the information processing system may include a plurality of the information processing devices. In this case, the respective processing circuits may be configured to update at least a part of the first vector and at least a part of the second vector in parallel.

### [Overall Processing for Solving Combinatorial Optimization Problem]

The following describes overall processing executed to solve a combinatorial optimization problem using the simulated bifurcation algorithm.

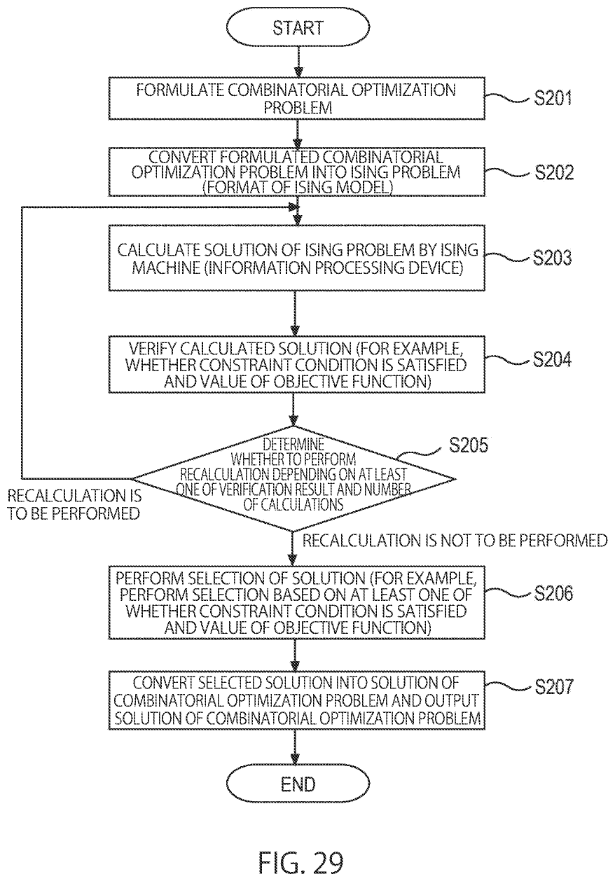

A flowchart of FIG. 29 illustrates an example of the overall processing executed to solve the combinatorial optimization problem. Hereinafter, processing will be described with reference to FIG. 29.

First, the combinatorial optimization problem is formulated (step S201). Then, the formulated combinatorial optimization problem is converted into an Ising problem (a format of an Ising model) (step S202). Next, a solution of the Ising problem is calculated by an Ising machine (information processing device) (step S203). Then, the calculated solution is verified (step S204). For example, in step S204, whether a constraint condition has been satisfied is confirmed. In addition, whether the obtained solution is an optimal solution or an approximate solution close thereto may be confirmed by referring to a value of an objective function in step S204.

Then, it is determined whether recalculation is to be performed depending on at least one of the verification result or the number of calculations in step S204 (step S205). When it is determined that the recalculation is to be performed (YES in step S205), the processes in steps S203 and S204 are executed again. On the other hand, when it is determined that the recalculation is not to be performed (NO in step S205), a solution is selected (step S206). For example, in step S206, the selection can be performed based on at least one of whether the constraint condition is satisfied or the value of the objective function. Note that the process of step S206 may be skipped when a plurality of solutions are not calculated. Finally, the selected solution is converted into a solution of the combinatorial optimization problem, and the solution of the combinatorial optimization problem is output (step S207).

When the information processing device, the information processing system, the information processing method, the storage medium, and the program described above are used, the solution of the combinatorial optimization problem can be calculated within the practical time. As a result, it becomes easier to solve the combinatorial optimization problem, and it is possible to promote social innovation and progress in science and technology.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An information processing device configured to repeatedly update a first vector, which has a first variable as an element, and a second vector, which has a second variable corresponding to the first variable as an element, the information processing device comprising:
a storage unit configured to store the first variable and the second variable; and
a processing circuit configured to
update the first vector by weighted addition of the corresponding second variable to the first variable,
update the second vector by weighting the first variable with a first coefficient that monotonically increases or monotonically decreases depending on a number of updates, adding the weighted first variable to the corresponding second variable, calculating a problem term using a plurality of the first variables, and adding the problem term to the second variable, and
repeat updating of the first vector and the second vector, then initialize the second variable of the second vector using a pseudo random number, and then repeat updating of the first vector and the second vector again.

2. The information processing device according to claim 1, wherein
the processing circuit is configured to change a maximum absolute value of the pseudo random number depending on a number of times of initialization of the second variable of the second vector.

3. The information processing device according to claim 1, wherein
the processing circuit is configured to monotonically decrease a maximum absolute value of the pseudo random number depending on a number of times of initialization of the second variable of the second vector.

4. The information processing device according to claim 1, wherein
the processing circuit is configured to repeat updating of the first vector and the second vector, then calculate a value of an objective function based on the first vector, store the first vector and the value of the objective function in the storage unit, and then repeat updating of the first vector and the second vector again.

5. The information processing device according to claim 1, wherein
the processing circuit is configured to repeat updating of the first vector and the second vector, then calculate a solution vector from the first vector by converting the first variable, which is a positive value, into a first value and converting the first variable, which is a negative value, into a second value smaller than the first value, calculate a value of an objective function based on the solution vector, store the solution vector and the value of the objective function in the storage unit, and then repeat updating of the first vector and the second vector again.

6. The information processing device according to claim 1, wherein
the pseudo random number generated by the processing circuit is a normal random number.

7. The information processing device according to claim 1, wherein
the pseudo random number generated by the processing circuit is a uniform random number.

8. The information processing device according to claim 1, wherein
the problem term calculated by the processing circuit is based on an Ising model.

9. The information processing device according to claim 8, wherein
the problem term calculated by the processing circuit includes a many-body interaction.

10. The information processing device according to claim 1, comprising
a plurality of the processing circuits,
wherein the respective processing circuits are configured to update at least a part of the first vector and at least a part of the second vector in parallel.

11. An information processing system configured to repeatedly update a first vector, which has a first variable as an element, and a second vector, which has a second variable corresponding to the first variable as an element, the information processing system comprising:
a storage device configured to store the first variable and the second variable; and
an information processing device configured to
update the first vector by weighted addition of the corresponding second variable to the first variable,
update the second vector by weighting the first variable with a first coefficient that monotonically increases or monotonically decreases depending on a number of updates, adding the weighted first variable to the corresponding second variable, calculating a problem term using a plurality of the first variables, and adding the problem term to the second variable, and
repeat updating of the first vector and the second vector, then initialize the second variable of the second vector using a pseudo random number, and then repeat updating of the first vector and the second vector again.

12. The information processing system according to claim 11, comprising
a plurality of the information processing devices,
wherein the respective information processing devices are configured to update at least a part of the first vector and at least a part of the second vector in parallel.

13. An information processing method for repeatedly updating a first vector, which has a first variable as an element, and a second vector, which has a second variable corresponding to the first variable as an element, the information processing method comprising:
a step of updating the first vector by weighted addition of the corresponding second variable to the first variable; and
a step of updating the second vector by weighting the first variable with a first coefficient that monotonically increases or monotonically decreases depending on a number of updates, adding the weighted first variable to the corresponding second variable, calculating a problem term using a plurality of the first variables, and adding the problem term to the second variable,
wherein the second variable of the second vector is initialized using a pseudo random number after repeating updating of the first vector and the second vector, and then repeat updating of the first vector and the second vector again.

14. A non-transitory computer-readable storage medium that stores a program for causing a computer to repeatedly update a first vector, which has a first variable as an element, and a second vector, which has a second variable corresponding to the first variable as an element, the program comprising:
a step of updating the first vector by weighted addition of the corresponding second variable to the first variable; and
a step of updating the second vector by weighting the first variable with a first coefficient that monotonically increases or monotonically decreases depending on a number of updates, adding the weighted first variable to the corresponding second variable, calculating a problem term using a plurality of the first variables, and adding the problem term to the second variable,
wherein the computer is caused to repeat updating of the first vector and the second vector, then initialize the second variable of the second vector using a pseudo random number, and then repeat updating of the first vector and the second vector again.
